(19) United States
(12) Patent Application Publication
(10) Pub. No.: US 2025/0040392 A1
(43) Pub. Date: Jan. 30, 2025

(54) DISPLAY DEVICE AND METHOD FOR FABRICATION THEREOF

(71) Applicant: Samsung Display Co., LTD., Yongin-si (KR)

(72) Inventors: Hee Kwang SONG, Yongin-si (KR); Ah Lang PARK, Yongin-si (KR)

(73) Assignee: Samsung Display Co., LTD., Yongin-si (KR)

(21) Appl. No.: 18/586,885

(22) Filed: Feb. 26, 2024

(30) Foreign Application Priority Data
Jul. 24, 2023 (KR) 10-2023-0096101

(51) Int. Cl. H10K 59/38; H10K 59/12; H10K 59/122; H10K 59/80; H10K 71/00

(52) U.S. Cl. CPC H10K 59/38; H10K 59/1201; H10K 59/122; H10K 59/877; H10K 59/879; H10K 71/00

(57) ABSTRACT

A display device includes a first substrate including a first emission area and a second emission area; a first light emitting element overlapping the first emission area and a second light emitting element overlapping the second emission area; a light transmitting layer disposed on the first light emitting element; a first wavelength conversion layer disposed on the second light emitting element; a capping layer disposed on the light transmitting layer and the first wavelength conversion layer; a low refractive layer disposed on the capping layer; and a second substrate disposed on the low refractive layer, wherein the capping layer includes a first surface facing the low refractive layer and a second surface opposite to the first surface, in the first emission area, the second surface of the capping layer includes a capping concave-convex pattern, and in the second emission area, the second surface of the capping layer is substantially flat.

### CROSS-REFERENCE TO RELATED APPLICATION(S)

This application claims priority to and benefits of Korean Patent Application No. 10-2023-0096101 under 35 U.S.C. 119, filed on Jul. 24, 2023, in the Korean Intellectual Property Office, the entire contents of which are incorporated herein by reference.

### BACKGROUND

### 1. Technical Field

Embodiments relate to a display device and a method for fabrication of the display device.

### 2. Description of the Related Art

The importance of display devices has steadily increased with the development of multimedia technology. Accordingly, various types of display devices such as a liquid crystal display (LCD) device, an organic light emitting diode (OLED) display device and the like have been developed.

Among the display devices, a self-light emitting display device includes a self-light emitting element such as an organic light emitting element. The self-light emitting element may include two opposite electrodes and a light emitting layer between the two opposite electrodes. In the case of using the organic light emitting element as the self-light emitting element, the electrons and holes from the two electrodes are recombined in the light emitting layer to produce excitons, which generate light as they transition from the excited state to the ground state.

The display device may include a color conversion element that implements color by receiving light from an organic light emitting element or the like. For example, the color conversion element receives blue light from the organic light emitting element and emits blue, green, and red colors, respectively, so that images having various colors may be visually recognized. The color conversion element may be disposed on a display device in the form of a separate substrate or may be formed by being directly integrated with elements in the display device.

### SUMMARY

Embodiments provide a display device having high light efficiency and high luminance.

Embodiments also provide a method for fabrication of a display device in which fabrication time is reduced.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a first substrate including a first emission area and a second emission area; a first light emitting element overlapping the first emission area and a second light emitting element overlapping the second emission area, the first and second light emitting elements disposed on the first substrate; a light transmitting layer disposed on the first light emitting element; a first wavelength conversion layer disposed on the second light emitting element; a capping layer disposed on the light transmitting layer and the first wavelength conversion layer; a low refractive layer disposed on the capping layer; and a second substrate disposed on the low refractive layer, wherein the capping layer may include a first surface facing the low refractive layer and a second surface opposite to the first surface, in the first emission area, the second surface of the capping layer may include a capping concave-convex pattern, and in the second emission area, the second surface of the capping layer may be substantially flat.

The first wavelength conversion layer may include a light scatterer, and the light transmitting layer may not include a light scatterer.

The capping concave-convex pattern may include a plurality of depressed portions, and each of the plurality of depressed portions of the capping concave-convex pattern may be recessed in a thickness direction.

The capping concave-convex pattern may include a plurality of island-like patterns separated from each other.

The capping concave-convex pattern may include a linear pattern extending in a direction.

A cross section of each of the plurality of depressed portions of the capping concave-convex pattern may have a half-round, half-ellipse, or segment of a circle shape.

A depth of each of the plurality of depressed portions of the capping concave-convex pattern may be equal to or greater than about 0.1 m, and a width of each of the plurality of depressed portions of the capping concave-convex pattern may be equal to or greater than about 3 m.

A distance between the adjacent depressed portions may be equal to or greater than about 1.5 m.

A refractive index of the light transmitting layer may be in a range of about 1.40 to about 1.70.

A refractive index of the capping layer may be greater than a refractive index of the low refractive layer, and a difference between the refractive index of the capping layer and the refractive index of the low refractive layer may be in a range of about 0.30 to about 0.60.

A refractive index of the capping layer may be in a range of about 1.40 to about 1.70, and a refractive index of the low refractive layer may be in a range of about 1.10 to about 1.30.

An upper surface of the light transmitting layer may be in contact with the second surface of the capping layer, and may comprise a concave-convex pattern engaged with the capping concave-convex pattern.

The second surface of the capping layer may be in contact with an upper surface of the first wavelength conversion layer in the second emission area, and the upper surface of the first wavelength conversion layer may be substantially flat.

The first wavelength conversion layer may include a base resin and a first wavelength conversion shifter.

According to an aspect of the disclosure, a display device may include a first substrate including a first emission area and a second emission area; a first light emitting element overlapping the first emission area and a second light emitting element overlapping the second emission area, the first and second light emitting elements disposed on the first substrate; a light transmitting layer disposed on the first light emitting element; a first wavelength conversion layer disposed on the second light emitting element; a capping layer disposed on the light transmitting layer and the first wavelength conversion layer; a low refractive layer disposed on the capping layer; a first color filter disposed on the low refractive layer, overlapping the first emission area, and including a light scatterer; a second color filter disposed on the low refractive layer and overlapping the second emission area; and a second substrate disposed on the first color filter and the second color filter.

The first wavelength conversion layer may include a light scatterer, and the light transmitting layer and the second color filter may not include a light scatterer.

The capping layer may include a first surface facing the low refractive layer and a second surface opposite to the first surface, in the first emission area, the second surface of the capping layer may include a capping concave-convex pattern, and in the second transmission area, the second surface of the capping layer may be substantially flat.

According to an aspect of the disclosure, a method for fabrication of a display device may include preparing a substrate including a first transmission area, a second transmission area, and a light blocking area surrounding the first transmission area and the second transmission area; forming a color filter layer on the substrate, forming a low refractive layer on the color filter layer, and forming a capping layer on the low refractive layer; forming a capping concave-convex pattern on an upper surface of the capping layer in the first transmission area; forming a bank pattern layer on the upper surface of the capping layer in the light blocking area; and forming a light transmitting layer on the upper surface of the capping layer in the first transmission area.

The method for fabrication of a display device may further include, between the forming of the bank pattern layer and the forming of the light transmitting layer, or after the forming of the light transmitting layer, forming a first wavelength conversion pattern layer on the upper surface of the capping layer in the second emission area.

The forming of the color filter layer on the substrate may include forming a first color filter on the substrate to overlap the first transmission area and not to overlap the second transmission area; and forming a second color filter on the substrate and the first color filter to overlap the second transmission area and not to overlap the first transmission area, wherein the first color filter may include a light scatterer, and the second color filter may not include a light scatterer.

In a display device and a method of fabricating the same according to an embodiment, a capping layer disposed on a light transmitting layer may include a concave-convex pattern, so that the display device may have high light efficiency and excellent luminance characteristics.

Also, in a display device and a method of fabricating the same according to an embodiment, the process of injecting a light scatterer into a light transmission layer may be omitted, and the manufacturing process time may be reduced.

However, the effects of the disclosure are not limited to the aforementioned effects, and various other effects are included in the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment;

FIG. 2 is a schematic cross-sectional view illustrating a cross section taken along line X1-X1′ of FIG. 1;

FIG. 3 is a schematic plan view of a display device according to an embodiment;

FIG. 4 is an enlarged schematic plan view of an area A1 of FIG. 3;

FIG. 5 is a schematic cross-sectional view illustrating a cross section taken along line X2-X2′ of FIG. 4;

FIG. 6 is an enlarged schematic plan view of an area A2 of FIG. 5;

FIG. 7 is a schematic perspective view illustrating a second capping layer in a first transmission area of a display device according to an embodiment;

FIG. 8 is a schematic perspective view illustrating a second capping layer in a first transmission area of a display device according to another embodiment;

FIG. 9 is a schematic cross-sectional view illustrating a cross section taken along line X3-X3′ of FIGS. 7 and 8;

FIG. 10 is a schematic cross-sectional view of a display device according to another embodiment;

FIG. 11 is an enlarged schematic view of an area A3 of FIG. 10;

FIG. 12 is a schematic cross-sectional view of a display device according to still another embodiment; and

FIGS. 13, 14, 15, 16, 17, 18, 19, and 20 are schematic diagrams for explaining a process of fabricating a second capping layer of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

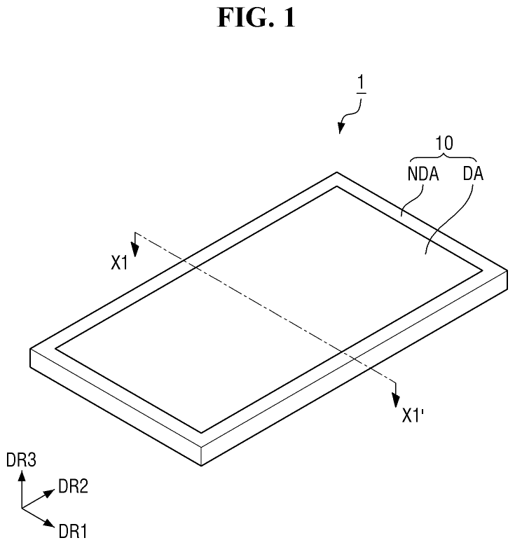

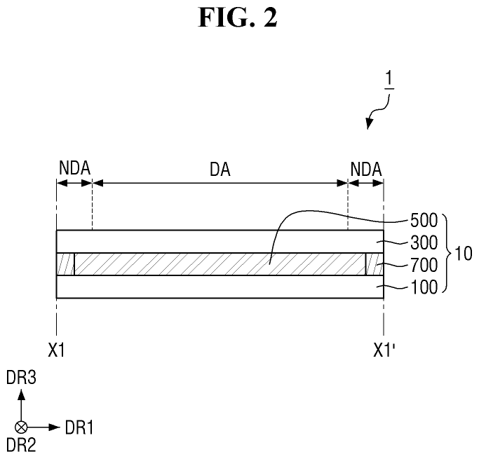

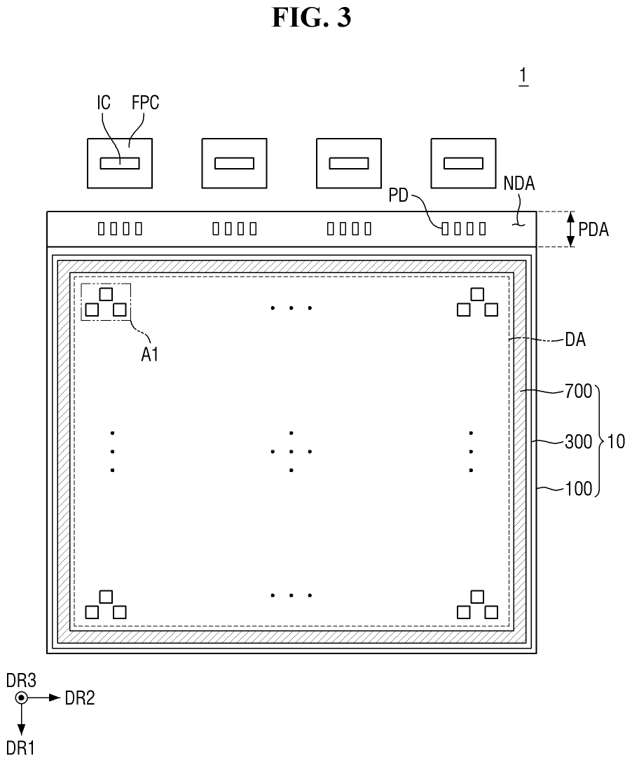

FIG. 1 is a schematic perspective view showing a display device according to an embodiment. FIG. 2 is a schematic cross-sectional view illustrating a cross section taken along line X1-X1′ of FIG. 1. FIG. 3 is a schematic plan view of a display device according to an embodiment.

Referring to FIGS. 1 and 2, a display device 1 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. In another example, the display device 1 according to an embodiment may be applied as a display unit of a television, a laptop, a monitor, a billboard, or an Internet-of-Things (IoT) terminal. These are merely suggested as examples, but the display device 1 may also be applied to other electronic devices without departing from the disclosure.

A first direction DR1, a second direction DR2, and a third direction DR3 are defined as shown in FIG. 1. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a vertical direction in the drawing, the second direction DR2 refers to a horizontal direction in the drawing, and the third direction DR3 refers to an upward and downward direction (i.e., a thickness direction) in the drawing. In the following disclosure, unless otherwise stated, “direction” may refer to both directions extending along the direction. Further, when it is desirable to distinguish both “directions” extending in sides (e.g., opposite sides), a side will be referred to as “a side in the direction” and another side will be referred to as “the another side in the direction.” Referring to FIG. 1, a direction in which an arrow is directed is referred to as a side, and the opposite direction is referred to as another side. Also, the third direction DR3 may be referred to as a thickness direction.

Hereinafter, for simplicity of description, when referring to the display device 1 or the surfaces of each member constituting the display device 1, a surface facing to a side in the direction in which the image is displayed, e.g., the third direction DR3 is referred to as a top surface, and the opposite surface of the surface is referred to as a bottom surface. However, embodiments are not limited thereto, and the surface and another surface of the member may be referred to as a front surface and a rear surface, respectively. In describing the relative position of each of the members of the display device 1, a side of the third direction DR3 may be referred to as an upper side and another side of the third direction DR3 may be referred to as a lower side.

The display device 1 may have a three-dimensional shape. For example, the display device 1 may have a rectangular parallelepiped shape or a three-dimensional shape similar thereto. In an embodiment, the display device 1 according to an embodiment may have a planar shape similar to a quadrilateral shape. For example, the display device 1 according to an embodiment may have a planar shape similar to a quadrilateral shape having short sides in the first direction DR1 and long sides in the second direction DR2, as shown in FIG. 1, but embodiments are not limited thereto. For example, in a planar shape of the display device 1 according to an embodiment, a corner at which a short side in the first direction DR1 and a long side in the second direction DR2 meet may be formed to be rounded and have a certain curvature or may be formed at a right angle, or may not be limited to a quadrilateral shape, and may be formed similarly to other polygonal shapes, a circular shape, or an elliptical shape.

The display device 1 may further include a display panel 10, a flexible circuit board FPC, and a driving chip. The display panel may include a display area DA in which an image is displayed and a non-display area NDA in which an image is not displayed. In an embodiment, the non-display area NDA may surround the edge portion of the display area DA, but embodiments are not limited thereto. An image displayed in the display area DA may be viewed by a user on a side in the third direction DR3 with reference to FIG. 1.

As illustrated in FIG. 2, the display panel 10 may include a light emitting portion 100 and a light transmitting portion 300 facing the light emitting portion 100, and may further include a sealing member 700 combining the light emitting portion 100 and the light transmitting portion 300 and a filling portion 500 filled between the light emitting portion 100 and the light transmitting portion 300.

The light emitting portion 100 may include elements and circuits for displaying an image, for example, a pixel circuit such as a switching element, a pixel defining layer 170 and a self-light emitting element that define emission area and a non-emission area, which will be described later, in the display area DA. In an embodiment, the self-light emitting element may include at least one of an organic light emitting diode, a quantum dot light emitting diode, an inorganic material-based micro light emitting diode (e.g., micro LED), or an inorganic material-based light emitting diode having a nano size (e.g., nano LED). Hereinafter, for simplicity of description, a case where the self-light emitting element is an organic light emitting element will be described as an example.

The light transmitting portion 300 may be positioned on the light emitting portion 100 and may face the light emitting portion 100. In an embodiment, the light transmitting portion 300 may include a color conversion pattern layer for converting a color of incident light emitted from the light emitting portion 100 and irradiated to the light transmitting portion 300. In an embodiment, the light transmitting portion 300 may include at least one of a color filter layer 320 or a light transmitting member, which will be described later, as the color conversion pattern layer. In an embodiment, the light transmitting portion 300 may include both the color filter layer 320 and the light transmitting member. The light transmitting member may include at least one of a wavelength conversion shifter or a light scatterer, as will be described later.

The sealing member 700 may be positioned between the light emitting portion 100 and the light transmitting portion 300 in the non-display area NDA. The sealing member 700 may be disposed along edge portions of the light emitting portion 100 and the light transmitting portion 300 in the non-display area NDA to surround the display area DA in plan view. The light emitting portion 100 and the light transmitting portion 300 may be coupled to each other via the sealing member 700.

In an embodiment, the sealing member 700 may be made of an organic material. For example, the sealing member 700 may be made of an epoxy-based resin, but embodiments are not limited thereto. In another embodiment, the sealing member 700 may be applied in the form of a frit including glass or the like.

The filling portion 500 may be positioned in a space between the light emitting portion 100 and the light transmitting portion 300 surrounded by the sealing member 700. The filling portion 500 may fill the space between the light emitting portion 100 and the light transmitting portion 300.

In an embodiment, the filling portion 500 may be made of a material that transmits light. In an embodiment, the filling portion 500 may be made of an organic material. For example, the filling portion 500 may be made of a silicone-based organic material, an epoxy-based organic material, a mixture of a silicone-based organic material and an epoxy-based organic material, or the like.

Referring to FIG. 3, the display device 1 may further include the flexible circuit board FPC and a driving chip in addition to the display panel 10.

The non-display area NDA of the display panel 10 may include a pad area PDA, and connection pads PD may be positioned in the pad area PDA. The pad area PDA may be defined on alight emitting portion 100. Accordingly, the connection pads PD may be disposed on the light emitting portion 100.

The flexible circuit board FPC may be connected to the connection pad PD. The flexible circuit board FPC may electrically connect the light emitting portion 100 to a circuit board and the like that provide a signal, power, and the like for driving the display device 1.

The driving chip IC may be electrically connected to the circuit board to receive data and a signal. In an embodiment, the driving chip IC may be a data driving chip IC, may receive a data control signal, image data, and the like from the circuit board and the like, and may generate and output a data voltage and the like corresponding to the image data.

In an embodiment, the driving chip IC may be mounted on the flexible circuit board FPC. For example, the driving chip IC may be mounted on the flexible circuit board FPC in the form of a chip on film (COF).

The data voltage provided from the driving chip IC, the power provided from the circuit board, and the like may be transmitted to the pixel circuit and the like of the light emitting portion 100 via the flexible circuit board FPC and the connection pad PD, as will be described later.

Hereinafter, emission areas defined in the light emitting portion 100 and transmission areas defined in the light transmitting portion 300 of the display panel 10 will be described in more detail.

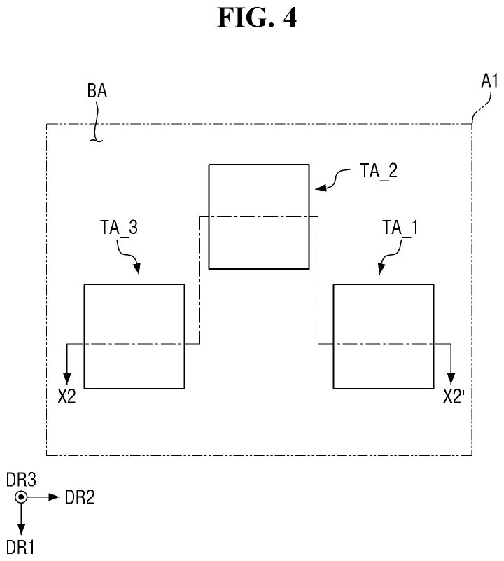

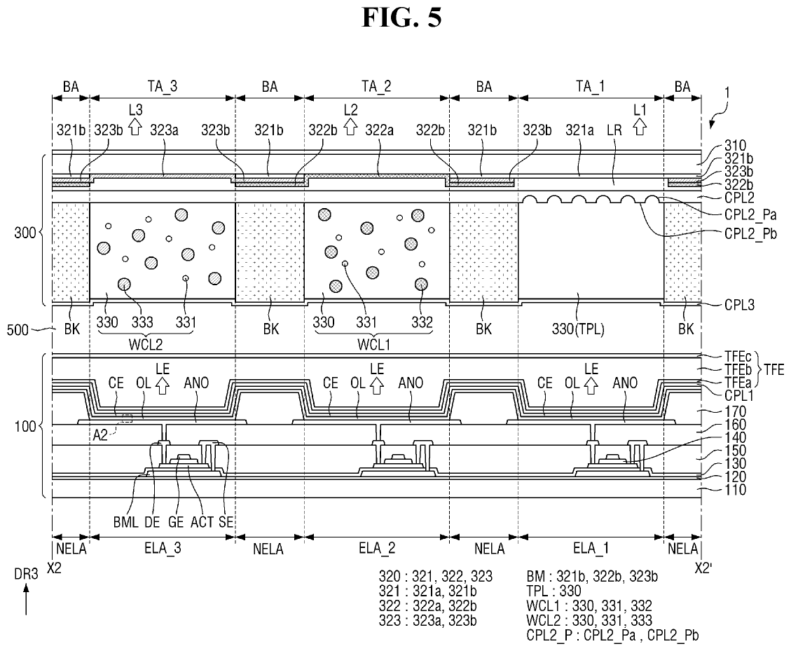

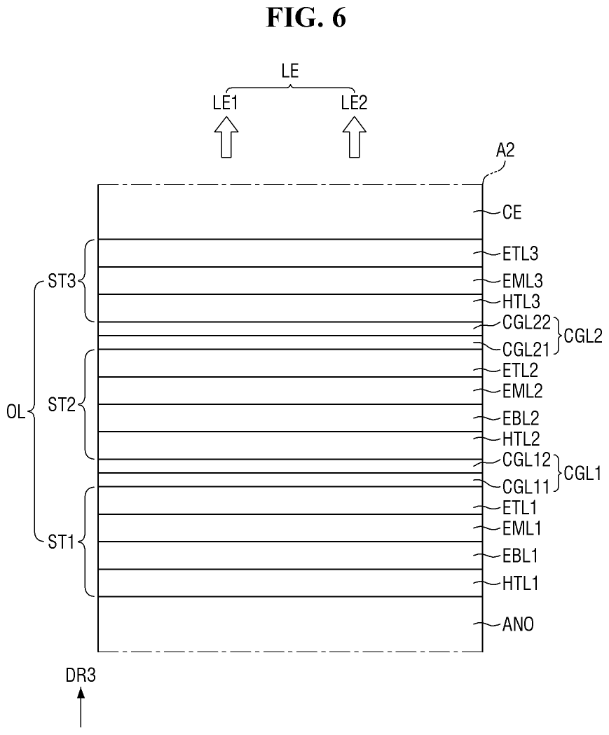

FIG. 4 is an enlarged schematic plan view of an area A1 of FIG. 3, and more specifically, a schematic plan view of a pixel group in the display panel of FIG. 3. FIG. 5 is a schematic cross-sectional view illustrating a cross section taken along line X2-X2′ of FIG. 4. FIG. 6 is an enlarged schematic plan view of an area A2 of FIG. 5.

Referring to FIGS. 4 and 5 in addition to FIG. 3, emission areas may be defined in the light emitting portion 100 of the display device 1 according to an embodiment, and transmission areas may be defined in the light transmitting portion 300.

The display area DA and the non-display area NDA defined in the display device 1 may be applied to the light emitting portion 100 and the light transmitting portion 300.

As illustrated in FIG. 4, in the display area DA of the light emitting portion 100, a first emission area ELA_1, a second emission area ELA_2, and a third emission area ELA_3 may be defined. The first emission area ELA_1, the second emission area ELA_2, and the third emission area ELA_3 may be areas in which light generated by the light emitting element of the light emitting portion 100 is emitted to the outside of the light emitting portion 100, and a non-emission area NELA may be an area in which light is not emitted to the outside of the light emitting portion 100. In an embodiment, the non-emission area NELA may surround the first emission area ELA_1, the second emission area ELA_2, and the third emission area ELA_3 within the display area DA, but embodiments are not limited thereto.

In an embodiment, light emitted to the outside from the first emission area ELA_1, the second emission area ELA_2, and the third emission area ELA_3 may be light of the first color. In an embodiment, the light of the first color may be blue light. In another embodiment, the light of the first color may be mixed light, and may be a mixture of two or more of blue light, green light, and red light. Red light may have a peak wavelength in a range of about 610 nm to about 650 nm, green light may have a peak wavelength in a range of about 510 nm to about 550 nm, and blue light may have a peak wavelength in a range of about 440 nm to about 480 nm. Here, the peak wavelength means a wavelength at which the intensity of light is maximum.

In an embodiment, as illustrated in FIG. 4, the first emission area ELA_1 and the third emission area ELA_3 may be sequentially positioned along the second direction DR2, and the second emission area ELA_2 may be positioned on a side of the separation space between the first emission area ELA_1 and the third emission area ELA_3, so that the first emission area ELA_1, the second emission area ELA_2, and the third emission area ELA_3 may form one group, and as illustrated in FIG. 3, one group formed by the first emission area ELA_1, the second emission area ELA_2, and the third emission area ELA_3 may be repeatedly disposed along the first direction DR1 and the second direction DR2 in the display area DA, but embodiments are not limited thereto. For example, the disposition of the first emission area ELA_1, the second emission area ELA_2, and the third emission area ELA_3 may be variously changed, so that the first emission area ELA_1, the second emission area ELA_2, and the third emission area ELA_3 may be sequentially positioned along the second direction DR2. Hereinafter, for simplicity of description, a case in which the first emission area ELA_1, the second emission area ELA_2, and the third emission area ELA_3 are disposed as illustrated in FIG. 4 will be described as an example.

In an embodiment, the area (or size) of the first emission area ELA_1, the area (or size) of the second emission area ELA_2, and the area (or size) of the third emission area ELA_3 may be substantially the same as each other, but embodiments are not limited thereto. For example, the area of the first emission area ELA_1, the area of the second emission area ELA_2, and the area of the third emission area ELA_3 may be different from each other. In an embodiment, the first emission area ELA_1, the second emission area ELA_2, and the third emission area ELA_3 may have a square shape in plan view, but embodiments are not limited thereto. Hereinafter, for simplicity of description, description will be made focusing on the fact that the first emission area ELA_1, the second emission area ELA_2, and the third emission area ELA_3 have a square planar shape and have substantially the same area.

A first transmission area TA_1, a second transmission area TA_2, and a third transmission area TA_3 may be defined in the display area DA of the light transmitting portion 300. The first transmission area TA_1, the second transmission area TA_2, and the third transmission area TA_3 may be areas through which the light generated in the first emission area ELA_1, the second emission area ELA_2, and the third emission area ELA_3 of the light emitting portion 100 passes (or transmits). A light blocking area BA may be positioned in the periphery of the first transmission area TA_1, the second transmission area TA_2, and the third transmission area TA_3 in the display area DA of the light transmitting portion 300. In an embodiment, the light blocking area BA may surround the first transmission area TA_1, the second transmission area TA_2, and the third transmission area TA_3, but embodiments are not limited thereto. For example, the light blocking area BA may be positioned in the non-display area NDA as well as the display area DA of the light transmitting portion 300.

The first transmission area TA_1 may correspond to (or overlap) the first emission area ELA_1, the second transmission area TA_2 may correspond to (or overlap) the second emission area ELA_2, and the third transmission area TA_3 may correspond to (or overlap) the third emission area ELA_3. In an embodiment, the first transmission area TA_1 and the first emission area ELA_1 may have substantially the same area (or same size). The first transmission area TA_1 may overlap (e.g., completely overlap) the first emission area ELA_1. The second transmission area TA_2 and the second emission area ELA_2 may have substantially the same area (or same size). The second transmission area TA_2 may overlap (e.g., completely overlap) the second emission area ELA_2. The third transmission area TA_3 and the third emission area ELA_3 may have substantially the same area (or same size). The third transmission area TA_3 may overlap (e.g., completely overlap) the third emission area ELA_3 However, embodiments are not limited thereto. For example, the first transmission area TA_1 may have a different area (or different size) from the first emission area ELA_1, the second transmission area TA_2 may have a different area (or different size) from the second emission area ELA_2, and the third transmission area TA_3 may have a different area (or different size) from the third emission area ELA_3. Hereinafter, for simplicity of description, description will be made focusing on the fact that the first transmission area TA_1 and the first emission area ELA_1 may have substantially the same area as each other, and the first transmission area TA_1 may overlap (e.g., completely overlap) the first emission area ELA_1, the second transmission area TA_2 and the second emission area ELA_2 may have substantially the same area as each other, and the second transmission area TA_2 may overlap (e.g., completely overlap) the second emission area ELA_2, and the third transmission area TA_3 and the third emission area ELA_3 may have substantially the same area as each other, and the third transmission area TA_3 may overlap (e.g., completely overlap) the third emission area ELA_3.

The first transmission area TA_1 and the third transmission area TA_3 may be sequentially positioned along the second direction DR2, and the second transmission area TA_2 may be positioned on a side of the separation space between the first transmission area TA_1 and the third transmission area TA_3, so that the first transmission area TA_1, the second transmission area TA_2, and the third transmission area TA_3 may form a pixel group (e.g., single pixel group). As illustrated in FIG. 3, pixel groups may be repeatedly disposed along the first direction DR1 and the second direction DR2 within the display area DA.

As described above, the light of the first color provided from the light emitting portion 100 may pass through the first transmission area TA_1, the second transmission area TA_2, and the third transmission area TA_3 to be provided to the outside of the display device 1. Light emitted from the first transmission area TA_1 to the outside of the display device 1 may be referred to as first emission light, light emitted from the second transmission area TA_2 to the outside of the display device 1 may be referred to as second emission light, and light emitted from the third transmission area TA_3 to the outside of the display device 1 may be referred to as third emission light. The first emission light may be light of a first color, the second emission light may be light of a second color, and the third emission light may be light of a third color. In an embodiment, the light of the first color may be blue light, the light of the second color may be green light, and the light of the third color may be red light.

Hereinafter, the structure of the display device 1 will be described in detail.

Referring to FIG. 5, as described above, the display device 1 may include the light emitting portion 100, the light transmitting portion 300 disposed on the light emitting portion 100 to face the light emitting portion 100, and the filling portion 500 interposed between the light emitting portion 100 and the light transmitting portion 300. Hereinafter, for simplicity of description, the light emitting portion 100, the light transmitting portion 300, and the filling portion 500 will be described in order.

The light emitting portion 100 may be a structure in which a first substrate 110, a buffer layer 120, a lower metal layer BML, a first insulating layer 130, a semiconductor layer ACT, a gate electrode GE, a gate insulating layer 140, a second insulating layer 150, a source/drain electrode, a third insulating layer 160, a light emitting element, the pixel defining layer 170, a first capping layer CPL1, and a thin film encapsulation layer TFE are sequentially stacked on a side of the third direction DR3.

The first substrate 110 of the light emitting portion 100 may function as a base of the light emitting portion 100. The first substrate 110 may be made of alight transmitting material. The first substrate 110 may be a glass substrate or a plastic substrate. In case that the first substrate 110 is a plastic substrate, the first substrate 110 may have flexibility. In an embodiment, in case that the first substrate 110 is a plastic substrate, the first substrate 110 may include polyimide, but embodiment are not limited thereto.

The buffer layer 120 of the light emitting portion 100 may be disposed on the first substrate 110. The buffer layer 120 may function to block foreign matter or moisture penetrating through the first substrate 110 to the element disposed on the buffer layer 120.

In an embodiment, the buffer layer 120 may include an inorganic material such as SiO₂, SiNₓ, or SiOₓN_{y}, and may be formed as a single layer or multilayer, but embodiment are not limited thereto.

The lower metal layer BML of the light emitting portion 100 may be disposed on the buffer layer 120. The lower metal layer BML may block external light or light emitted from a light emitting element to be described later from being introduced into the semiconductor layer ACT. Accordingly, it is possible to prevent or reduce the occurrence of leakage current due to light in the thin film transistor to be described later.

The lower metal layer BML may be made of a material that blocks light and has conductivity. In an embodiment, the lower metal layer BML may include a single material of metal such as silver (Ag), nickel (Ni), gold (Au), platinum (Pt), aluminum (Al), copper (Cu), molybdenum (Mo), titanium (Ti), or neodium (Nd), or an alloy thereof. In an embodiment, the lower metal layer BML may have a single-layer structure or multilayer structure. For example, in case that the lower metal layer BML has a multilayer structure, the lower metal layer BML may have a stacked structure of titanium (Ti)/copper (Cu)/indium tin oxide (ITO), or a stacked structure of titanium (Ti)/copper (Cu)/aluminum oxide (Al₂O₃), but embodiment are not limited thereto.

In an embodiment, lower metal layers BML may be provided to respectively correspond to the semiconductor layers ACT and may overlap the semiconductor layers ACT. In an embodiment, the width of the lower metal layer BML may be greater than the width of the semiconductor layer ACT.

In an embodiment, the lower metal layer BML may be a part of a data line, a power supply line, a line that electrically connects the thin film transistor and the thin film transistor (GE, ACT, DE, and SE in FIG. 5) illustrated in the drawing to each other, and the like. In an embodiment, the lower metal layer BML may be made of a material having a lower resistance than the resistance of the source electrode SE and the drain electrode DE.

The first insulating layer 130 of the light emitting portion 100 may be disposed on the lower metal layer BML. The first insulating layer 130 may function to electrically insulate the lower metal layer BML from the semiconductor layer ACT. The first insulating layer 130 may cover the lower metal layer BML.

In an embodiment, the first insulating layer 130 may include an inorganic material such as SiO₂, SiNₓ, SiOₓN_{y}, Al₂O₃, TiO₂, Ta₂O, HfO₂, or ZrO₂, but embodiment are not limited thereto.

The semiconductor layer ACT of the light emitting portion 100 may be disposed on the first insulating layer 130. The semiconductor layer ACT may be disposed to correspond to (or to overlap) each of the first emission area ELA_1, the second emission area ELA_2, and the third emission area ELA_3 in the display area DA of the light emitting portion 100. Further, the semiconductor layer ACT may overlap the lower metal layer BML, thereby suppressing generation of a photocurrent in the semiconductor layer ACT.

The semiconductor layer ACT may include an oxide semiconductor. In an embodiment, the semiconductor layer ACT may be formed of a zinc (Zn) oxide-based material, e.g., Zn oxide, In—Zn oxide, or Ga—In—Zn oxide, and may be an In—Ga—Zn—O (IGZO) semiconductor including a metal such as indium (In) or gallium (Ga), but embodiment are not limited thereto. For example, the semiconductor layer ACT may include amorphous silicon or polysilicon.

The gate electrode GE of the light emitting portion 100 may be disposed on the semiconductor layer ACT. The gate electrode GE may overlap the semiconductor layer ACT in the display area DA. In an embodiment, the width of the gate electrode GE may be narrower than the width of the semiconductor layer ACT, but embodiment are not limited thereto.

In an embodiment, the gate electrode GE may include one or more materials of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) in consideration of adhesion with an adjacent layer, surface flatness of a stacked layer, processability, and the like, and may be formed into a single layer or multiple layers, but embodiment are not limited thereto.

The gate insulating layer 140 of the light emitting portion 100 may be disposed between the semiconductor layer ACT and the gate electrode GE. The gate insulating layer 140 may insulate the semiconductor layer ACT from the gate electrode GE. In an embodiment, the gate insulating layer 140 may not be constituted with a single layer disposed on a side of the first substrate 110 in the third direction DR3 but be constituted with a partially patterned shape, and the width of the gate insulating layer 140 may be narrower than the width of the semiconductor layer ACT and be wider than the width of the gate electrode GE, but embodiment are not limited thereto.

In an embodiment, the gate insulating layer 140 may include an inorganic material. For example, the gate insulating layer 140 may include the inorganic material as an example in the description of the first insulating layer 130.

The second insulating layer 150 of the light emitting portion 100 may be disposed on the gate insulating layer 140 to cover the semiconductor layer ACT and the gate electrode GE. In an embodiment, the second insulating layer 150 may function as a planarization layer providing a flat surface.

The second insulating layer 150 may include an organic material. In an embodiment, the second insulating layer 150 may include at least one of photo acryl (PAC), polystylene, polymethylmethacrylate (PMMA), polyacrylonitrile (PAN), polyamide, polyimide, polyarylether, heterocyclic polymer, parylene, fluorine-based polymer, epoxy resin, benzocyclobutene-based resin, siloxane-based resin, or silane resin, but embodiments are not limited thereto.

The source electrode SE and the drain electrode DE of the light emitting portion 100 may be spaced apart from each other and disposed on the second insulating layer 150. The source electrode SE and the drain electrode DE may be connected to the semiconductor layer ACT through contact holes penetrating the second insulating layer 150, respectively. In an embodiment, the source electrode SE may penetrate the first insulating layer 130 as well as the second insulating layer 150 and may be connected to the lower metal layer BML. In case that the lower metal layer BML is a part of a line that transmits a signal, a voltage, and the like, the source electrode SE may be connected and electrically connected to the lower metal layer BML to receive a transmitted voltage and the like provided to the line. In another example, in case that the lower metal layer BML is a floating pattern rather than a separate line, a voltage and the like provided to the source electrode SE may be transmitted to the lower metal layer BML and the like.

The source electrode SE and the drain electrode DE may include aluminum (Al), copper (Cu), titanium (Ti), and the like, and may be formed as a multilayer or a single layer. In an embodiment, the source electrode SE and the drain electrode DE may have a multilayer structure of Ti/Al/Ti, but embodiment are not limited thereto.

The semiconductor layer ACT, the gate electrode GE, the source electrode SE, and the drain electrode DE described above may form a thin film transistor that is a switching element. In an embodiment, the thin film transistor may be positioned in each of the first emission area ELA_1, the second emission area ELA_2, and the third emission area ELA_3. In an embodiment, a part of the thin film transistor may be positioned in the non-emission area NELA.

The third insulating layer 160 of the light emitting portion 100 may be disposed on the second insulating layer 150 to cover the thin film transistor. In an embodiment, the third insulating layer 160 may be a planarization layer.

The third insulating layer 160 may be made of an organic material. In an embodiment, the third insulating layer 160 may include an acrylic resin, an epoxy resin, an imide resin, an ester resin, and the like, or may include a photosensitive organic material, but embodiment are not limited thereto.

Anode electrodes ANO may be positioned on the third insulating layer 160 in the display area DA of the light emitting portion 100. The anode electrodes ANO may be spaced apart from each other.

The anode electrodes ANO may overlap the first emission area ELA_1, the second emission area ELA_2, and the third emission area ELA_3, respectively, and may extend at least partially to the non-emission area NELA. The anode electrodes ANO may be connected to the drain electrode DE of the thin film transistor.

In an embodiment, the anode electrode ANO may be reflective electrodes, in which case the anode electrode ANO may be a metal layer including a metal such as Ag, Mg, Al, Pt, Pd, Au, Ni, Nd, Ir, or Cr. In another embodiment, the anode electrode ANO may further include a metal oxide layer stacked on the metal layer. In an embodiment, the anode electrode ANO may have a multilayer structure, for example, a two-layer structure of ITO/Ag, Ag/ITO, ITO/Mg, and ITO/MgF, or a three-layer structure of ITO/Ag/ITO.

The pixel defining layer 170 of the light emitting portion 100 may be disposed on the anode electrode ANO. The pixel defining layer 170 may define the first emission area ELA_1, the second emission area ELA_2, and the third emission area ELA_3 as openings exposing the anode electrodes ANO, respectively. The pixel defining layer 170 may overlap edge portions of the anode electrodes ANO.

The pixel defining layer 170 may overlap the light blocking area BA of the color filter layer 320 to be described later in the third direction DR3. For example, the pixel defining layer 170 may overlap a bank pattern layer BK, which will be described later, in the third direction DR3.

In an embodiment, the pixel defining layer 170 may include an organic insulating material selected from the group consisting of acrylic resin, epoxy resin, phenolic resin, polyamide resin, polyimide resin, unsaturated polyester resin, polyphenylene resin, polyphenylenesulfide resin and benzocyclobutene (BCB), but embodiment are not limited thereto.

A light emitting layer OL of the light emitting portion 100 may be disposed on the anode electrode ANO. In an embodiment, the light emitting layer OL may have a shape of a continuous film formed over the emission areas and the non-emission area NELA. In an embodiment, the light emitting layer OL may be positioned only in the display area DA, but embodiment are not limited thereto. For example, a part of the light emitting layer OL may be further disposed in the non-display area NDA. A more detailed description of the light emitting layer OL will be given later.

The cathode electrode CE of the light emitting portion 100 may be disposed on the light emitting layer OL. In an embodiment, the cathode electrode CE may be disposed on the light emitting layer OL to have a continuous film shape formed over the emission areas ELA_1, ELA_2, and ELA_3 and the non-emission area NELA. For example, the cathode electrode CE may cover (e.g., completely cover) the light emitting layer OL.

The cathode electrode CE may have a semi-transmissive property or transmissive property. In case that the cathode electrode CE has a thickness of tens to hundreds of angstroms, the cathode electrode CE may have a semi-transmissive property. In an embodiment, in case that the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or mixture thereof, such as a mixture of Ag and Mg. For example, the cathode electrode CE may include a transparent conductive oxide to have a transmissive property. In an embodiment, in case that the cathode electrode CE has the transmissive property, the cathode electrode CE may include tungsten oxide (WXOX), titanium oxide (TiO₂), indium tin oxide (ITO), indium zinc oxide (IZO), zinc oxide (ZnO), indium tin zinc oxide (ITZO), magnesium oxide (MgO), or the like.

The anode electrode ANO, the light emitting layer OL, and the cathode electrode CE may form light emitting elements. For example, the anode electrode ANO, the light emitting layer OL, and the cathode electrode CE overlapping the first emission area ELA_1 may form a first light emitting element, the anode electrode ANO, the light emitting layer OL, and the cathode electrode CE overlapping the second emission area ELA_2 may form a second light emitting element, and the anode electrode ANO, the light emitting layer OL, and the cathode electrode CE overlapping the third emission area ELA_3 may form a third light emitting element. Each of the first light emitting element, the second light emitting element, and the third light emitting element may emit emission light LE.

Referring to FIG. 6, the emission light LE emitted from the light emitting layer OL may be a mixed light in which a first component LE1 and a second component LE2 are mixed. Each of the first component LE1 and the second component LE2 in the emission light LE may have a peak wavelength within a range of about 440 nm to about 480 nm. For example, the emission light LE may be blue light.

In an embodiment, as illustrated in FIG. 6, the light emitting layer OL may have a structure in which light emitting material layers are superimposed, for example, a tandem structure. For example, the light emitting layer OL may include a first stack ST1 including a first light emitting material layer EML1, a second stack ST2 positioned on the first stack ST1 and including a second light emitting material layer EML2, a third stack ST3 positioned on the second stack ST2 and including a third light emitting material layer EML3, a first charge generation layer CGL1 positioned between the first stack ST1 and the second stack ST2, and a second charge generation layer positioned between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other.

In an embodiment, all the first light emitting material layer EML1, the second light emitting material layer EML2, and the third light emitting material layer EML3 may emit light of the first color, e.g., blue light. For example, each of the first light emitting material layer EML1, the second light emitting material layer EML2, and the third light emitting material layer EML3 may be a blue light emitting layer, and may include an organic material.

In an embodiment, at least one of the first light emitting material layer EML1, the second light emitting material layer EML2, or the third light emitting material layer EML3 may emit a first blue light having a first peak wavelength, and at least another one of the first light emitting material layer EML1, the second light emitting material layer EML2, or the third light emitting material layer EML3 may emit a second blue light having a second peak wavelength different from the first peak wavelength. For example, any one of the first light emitting material layer EML1, the second light emitting material layer EML2, and the third light emitting material layer EML3 may emit the first blue light having the first peak wavelength, and the other two of the first light emitting material layer EML1, the second light emitting material layer EML2, and the third light emitting material layer EML3 may emit the second blue light having the second peak wavelength. For example, the emission light LE emitted from the light emitting layer OL may be a mixed light in which the first component LE1 and the second component LE2 are mixed, and the first component LE1 may be the first blue light having the first peak wavelength, and the second component LE2 may be the second blue light having the second peak wavelength.

In an embodiment, one of the first peak wavelength and the second peak wavelength may be in a range of about 440 nm to about 460 nm, and the other one thereof may be in a range of about 460 nm to about 480 nm. However, the range of the first peak wavelength and the range of the second peak wavelength are not limited thereto. For example, both the range of the first peak wavelength and the range of the second peak wavelength may include about 460 nm. In an embodiment, one of the first blue light and the second blue light may be deep blue color, and the other one thereof may be sky blue color.

In accordance with an embodiment, the emission light LE emitted from the light emitting layer OL may be blue light, and may include a long wavelength component and a short wavelength component. Therefore, the light emitting layer OL may emit blue light having an emission peak in a broader wavelength range as the emission light LE. Accordingly, there is an advantage in that color visibility may be improved at a side viewing angle compared to a conventional light emitting element emitting blue light having a sharp emission peak.

In an embodiment, each of the first light emitting material layer EML1, the second light emitting material layer EML2, and the third light emitting material layer EML3 may include a host and a dopant. A material of the host is not particularly limited as long as it is generally used. For example, tris(8-hydroxyquinolinato)aluminium (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN), and the like may be used.

Each of the first light emitting material layer EML1, the second light emitting material layer EML2, and the third light emitting material layer EML3 emitting blue light may include, e.g., a fluorescent material including any one selected from the group consisting of spiro-DPVBi, spiro-6P, distyryl-benzene (DSB), distyryl-arylene (DSA), polyfluorene (PFO)-based polymer, and poly(p-phenylene vinylene) (PPV)-based polymer. As another example, a phosphorescent material including an organometallic complex such as (4,6-F₂ppy)₂Ir(pic) may be included.

As described above, at least one of the first light emitting material layer EML1, the second light emitting material layer EML2, and the third light emitting material layer EML3 may emit blue light in a different wavelength range from at least another one of the first light emitting material layer EML1, the second light emitting material layer EML2, and the third light emitting material layer EML3. In order to emit blue light in different wavelength ranges, the first light emitting material layer EML1, the second light emitting material layer EML2, and the third light emitting material layer EML3 may include the same material, and a resonance distance may be adjusted. In another example, in order to emit blue light in different wavelength ranges, at least one of the first light emitting material layer EML1, the second light emitting material layer EML2, and the third light emitting material layer EML3, and at least another one of the first light emitting material layer EML1, the second light emitting material layer EML2, and the third light emitting material layer EML3 may include different materials from each other.

However, embodiments are not limited thereto, and the first light emitting material layer EML1, the second light emitting material layer EML2, and the third light emitting material layer EML3 may emit blue light having a peak wavelength within a range of about 440 nm to about 480 nm, and may be made of the same material.

In another embodiment, at least anyone of the first light emitting material layer EML1, the second light emitting material layer EML2, or the third light emitting material layer EML3 may emit the first blue light having the first peak wavelength, another one of the first light emitting material layer EML1, the second light emitting material layer EML2, and the third light emitting material layer EML3 may emit the second blue light having the second peak wavelength different from the first peak wavelength, and the other one of the first light emitting material layer EML1, the second light emitting material layer EML2, and the third light emitting material layer EML3 may emit third blue light having a third peak wavelength different from the first peak wavelength and the second peak wavelength. In another embodiment, any one of the first peak wavelength, the second peak wavelength, and the third peak wavelength may be within a range of about 440 nm to about 460 nm. Another one of the first peak wavelength, the second peak wavelength, and the third peak wavelength may be within a range of about 460 nm to about 470 nm, and the other one of the first peak wavelength, the second peak wavelength, and the third peak wavelength may be within a range of about 470 nm to about 480 nm.

According to another embodiment, the emission light LE emitted from the light emitting layer OL may be blue light and may include a long wavelength component, an intermediate wavelength component, and a short wavelength component. Therefore, the light emitting layer OL may emit blue light having an emission peak in a broader wavelength range as the emission light LE, thereby improving the color visibility at a side viewing angle.

In accordance with the above-described embodiments, compared to the conventional light emitting element that does not adopt a tandem structure, i.e., a structure in which light emitting layers OL are stacked, it is advantageous in that the light efficiency increases and the lifespan of the display device 1 increases.

In another embodiment, at least one of the first light emitting material layer EML1, the second light emitting material layer EML2, or the third light emitting material layer EML3 may emit light of the first color, e.g., blue light, and at least another one of the first light emitting material layer EML1, the second light emitting material layer EML2, or the third light emitting material layer EML3 may emit light of the second color, e.g., green light. In another embodiment, the range of the peak wavelength of blue light emitted by at least one of the first light emitting material layer EML1, the second light emitting material layer EML2, or the third light emitting material layer EML3 may be within a range of about 440 nm to about 480 nm. The green light emitted from at least one of the first light emitting material layer EML1, the second light emitting material layer EML2, or the third light emitting material layer EML3 may have a peak wavelength within a range of about 510 nm to about 550 nm.

For example, any one of the first light emitting material layer EML1, the second light emitting material layer EML2, and the third light emitting material layer EML3 may be a green light emitting layer that emits green light, and the other two among the first light emitting material layer EML1, the second light emitting material layer EML2, and the third light emitting material layer EML3 may be blue light emitting layers that emit blue light. In case that the other two among the first light emitting material layer EML1, the second light emitting material layer EML2, and the third light emitting material layer EML3 are the blue light emitting layers, the peak wavelength ranges of the blue lights emitted by the two blue light emitting layers may be the same, or may be different from each other.

In accordance with yet another embodiment, the emission light LE emitted from the light emitting layer OL may be a mixed light in which the first component LE1 that is blue light and the second component LE2 that is green light are mixed. For example, in case that the first component LE1 is deep blue light and the second component LE2 is green light, the emission light LE may be sky blue light. Similarly to the above-described embodiments, the emission light LE emitted from the light emitting layer OL, which is a mixture of blue light and green light, may include a long wavelength component and a short wavelength component. Therefore, the light emitting layer OL may emit blue light having an emission peak in a broader wavelength range as the emission light LE, thereby improving the color visibility at a side viewing angle. For example, since the second component LE2 of the emission light LE is green light, the green light component of the light provided from the display device 1 to the outside may be supplemented, thereby improving the color reproducibility of the display device 1.

In yet another embodiment, the green light emitting layer among the first light emitting material layer EML1, the second light emitting material layer EML2, and the third light emitting material layer EML3 may include a host and a dopant. A material of the host including the green light emitting layer is not particularly limited as long as it is generally used. For example, tris(8-hydroxyquinolinato)aluminium (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN), and the like may be used.

The dopant included in the green light emitting layer may include a fluorescent material including, for example, tris(8-hydroxyquinolinato)aluminium(III) (Alq₃), or a phosphorescent material such as fac tris(2-phenylpyridine)iridium (Ir(ppy)₃), bis(2-phenylpyridine)(acetylacetonate)iridium(III) (Ir(ppy)₂(acac)), and Tris[2-(p-tolyl)pyridine]iridium(III) (Ir(mpyp)₃).

The first charge generation layer CGL1 may be positioned between the first stack ST1 and the second stack ST2. The first charge generation layer CGL1 may function to inject electric charge into each light emitting layer OL. The first charge generation layer CGL1 may function to control charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11, and between the n-type charge generation layer CGL11 and the second stack ST2.

The first charge generation layer CGL1 may have a structure in which the n-type charge generation layer CGL11 and the p-type charge generation layer CGL12 are in contact with each other. The n-type charge generation layer CGL11 may be disposed closer to the anode electrode ANO between the anode electrode ANO and the cathode electrode CE. The p-type charge generation layer CGL12 may be disposed closer to the cathode electrode CE between the anode electrode ANO and the cathode electrode CE. The n-type charge generation layer CGL11 may supply electrons to the first light emitting material layer EML1 adjacent to the anode electrode ANO, and the p-type charge generation layer CGL12 may supply holes to the second light emitting material layer EML2 included in the second stack ST2. The first charge generation layer CGL1 may be disposed between the first stack ST1 and the second stack ST2 to provide electric charge to each light emitting material layer, thereby increasing luminous efficiency and decreasing a driving voltage.

The first stack ST1 may be positioned on the anode electrode ANO, and may further include a first hole transport layer HTL1, a first electron block layer EBL1, the first light emitting material layer EML1, and a first electron transport layer ETL1.

The first hole transport layer HTL1 may be positioned on the anode electrode ANO. The first hole transport layer HTL1 may function to facilitate the transport of holes and may include a hole transport material. The hole transport material may include a carbazole-based derivative such as N-phenylcarbazole and polyvinylcarbazole, a fluorene-based derivative, a triphenylamine-based derivative such as N,N′-bis(3-methylphenyl)-N,N′-diphenyl)-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-Cyclohexylidene bis[N,N-bis(4-methylphenyl)benzenamine] (TAPC), or the like, but embodiments are not limited thereto.

The first electron block layer EBL1 may be positioned on the first hole transport layer HTL1, and between the first hole transport layer HTL1 and the first light emitting material layer EML1. The first electron block layer EBL1 may include a hole transport material and a metal or metal compound to prevent electrons generated in the first light emitting material layer EML1 from moving into the first hole transport layer HTL1. In an embodiment, the first hole transport layer HTL1 and the first electron block layer EBL1 described above may be formed as a single layer in which respective materials are mixed.

The first electron transport layer ETL1 may be positioned on the first light emitting material layer EML1, and between the first charge generation layer CGL1 and the first light emitting material layer EML1. In an embodiment, the first electron transport layer ETL1 may include an electron transport material such as tris(8-hydroxyquinolinato)aluminum (Alq₃), 1,3,5-tri(1-phenyl-1H-benzo[d]imidazol-2-yl)phenyl (TPBi), 2,9-dimethyl-4,7-diphenyl-1,10-phenanthroline (BCP), (4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebg2), 9,10-di(naphthalene-2-yl)anthracene (ADN), and a mixture thereof. However, embodiments are not limited to the type of the electron transport material. The second stack ST2 may be positioned on the first charge generation layer CGL1, and further include a second hole transport layer HTL2, a second electron block layer EBL2, the second light emitting material layer EML2, and a second electron transport layer ETL2.

The second hole transport layer HTL2 may be positioned on the first charge generation layer CGL1. The second hole transport layer HTL2 and the first hole transport layer HTL1 may be made of the same material as each other. In another example, the second hole transport layer HTL2 may include one or more materials selected from examples of materials included in the first hole transport layer HTL1. The second hole transport layer HTL2 may be formed as a single layer or a plurality of layers.

The second electron block layer EBL2 may be positioned on the second hole transport layer HTL2, and between the second hole transport layer HTL2 and the second light emitting material layer EML2. The second electron block layer EBL2 and the first electron block layer EBL1 may be formed of the same material and the same structure as each other. In another example, the second electron block layer EBL2 may include one or more materials selected from examples of materials included in the first electron block layer EBL1.

The second electron transport layer ETL2 may be positioned on the second light emitting material layer EML2, and between the second charge generation layer CGL2 and the second light emitting material layer EML2. The second electron transport layer ETL2 and the first electron transport layer ETL1 may be formed of the same material and the same structure as each other. In another example, the second electron transport layer ETL2 may include one or more materials selected from examples of materials included in the first electron transport layer ETL1. The second electron transport layer ETL2 may be formed as a single layer or a plurality of layers.

The second charge generation layer CGL2 may be positioned on the second stack ST2 and between the second stack ST2 and the third stack ST3.

The second charge generation layer CGL2 and the first charge generation layer CGL1 may have the same structure as each other described above. For example, the second charge generation layer CGL2 may include an n-type charge generation layer CGL21 disposed closer to the second stack ST2 and a p-type charge generation layer CGL22 disposed closer to the cathode electrode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may be made of different materials, or may be made of the same material.

The third stack ST3 may be positioned on the second charge generation layer CGL2 and may further include a third hole transport layer HTL3, a third light emitting material layer EML3, and a third electron transport layer ETL3.

The third hole transport layer HTL3 may be positioned on the second charge generation layer CGL2. The third hole transport layer HTL3 and the first hole transport layer HTL1 may be made of the same material. In another example, the third hole transport layer HTL3 may include one or more materials selected from examples of materials included in the first hole transport layer HTL1. The third hole transport layer HTL3 may be formed as a single layer or a plurality of layers. In case that the third hole transport layer HTL3 is formed as a plurality of layers, each layer may include a different material.

The third electron transport layer ETL3 may be positioned on the third light emitting material layer EML3, and between the cathode electrode CE and the third light emitting material layer EML3. The third electron transport layer ETL3 and the first electron transport layer ETL1 may be formed of the same material and the same structure as each other. In another example, the third electron transport layer ETL3 may include one or more materials selected from examples of materials included in the first electron transport layer ETL1. The third electron transport layer ETL3 may be formed as a single layer or a plurality of layers. In case that the third electron transport layer ETL3 is formed as a plurality of layers, each layer may include a different material.

For example, a hole injection layer may be further positioned in at least one of the respective spaces between the first hole transport layer HTL1 and the anode electrode ANO, between the second hole transport layer HTL2 and the first charge generation layer CGL1, and between the third hole transport layer HTL3 and the second charge generation layer CGL2. The hole injection layer may function to smoothly inject holes into the first light emitting material layer EML1, the second light emitting material layer EML2, and the third light emitting material layer EML3. In an embodiment, the hole injection layer may be made of one or materials selected from the group consisting of copper phthalocyanine (CuPc), poly(3,4)-ethylenedioxythiophene (PEDOT), polyaniline (PANI), and N,N-dinaphthyl-N,N′-diphenyl benzidine (NPD), but embodiments are not limited thereto.

For example, an electron injection layer may be further positioned at least one of: between the third electron transport layer ETL3 and the cathode electrode CE, between the second charge generation layer CGL2 and the second electron transport layer ETL2, or between the first charge generation layer CGL1 and the first electron transport layer ETL1. The electron injection layer may function to facilitate electron injection, and may be made of tris(8-hydroxyquinolino)aluminum (Alq₃), PBD, TAZ, spiro-PBD, BAlq, or SAlq, but embodiments are not limited thereto. Further, the electron injection layer may be a metal halide compound, and may include one or more materials selected from the group consisting of MgF₂, LiF, NaF, KF, RbF, CsF, FrF, LiI, NaI, KI, RbI, CsI, FrI and CaF₂, but embodiments are not limited thereto. Further, the electron injection layer may include a lanthanum-based material such as Yb, Sm, Eu, or the like. In another example, the electron injection layer may include both the metal halide material and the lanthanum-based material, such as RbI:Yb, KI:Yb, or the like. In case that the electron injection layer includes both the metal halide material and the lanthanum-based material, the electron injection layer may be formed by co-deposition of the metal halide material and the lanthanum-based material.

In an embodiment, the light emitting layer OL may not include a red light emitting material layer, and thus may not emit red light. For example, the emission light LE may not include a light component having a peak wavelength of about 610 nm to about 650 nm, and the emission light LE may include only a light component having a peak wavelength of about 440 nm to about 550 nm.

Referring back to FIG. 5, a first capping layer CPL1 may be disposed on the cathode electrode CE. The first capping layer CPL1 may function to improve viewing angle characteristics and increase external luminous efficiency. The first capping layer CPL1 may be commonly disposed in the first emission area ELA_1, the second emission area ELA_2, the third emission area ELA_3, and the non-emission area NELA. The first capping layer CPL1 may cover (e.g., completely cover) the cathode electrode CE.

The first capping layer CPL1 may include at least one of an inorganic material having alight transmissive property or an organic material. For example, the first capping layer CPL1 may be formed of an inorganic layer, formed of an organic layer, or formed of an organic layer including inorganic particles. In an embodiment, the first capping layer CPL1 may include a triamine derivative, a carbazole biphenyl derivative, an arylenediamine derivative, an aluminum chelate compound (Alq₃), or the like, but embodiment are not limited thereto.

A thin film encapsulation layer TFE of the light emitting portion 100 may be disposed on the first capping layer CPL1. The thin film encapsulation layer TFE may function to protect components positioned under the thin film encapsulation layer TFE from external foreign matter such as moisture. The thin film encapsulation layer may be commonly disposed in the first emission area ELA_1, the second emission area ELA_2, the third emission area ELA_3, and the non-emission area NELA. The thin film encapsulation layer TFE may cover (e.g., completely cover) the first capping layer CPL1.

The thin film encapsulation layer TFE may include a lower inorganic encapsulation layer TFEa, an organic encapsulation layer TFEb, and an upper inorganic encapsulation layer TFEc sequentially stacked on the first capping layer CPL1.

The lower inorganic encapsulation layer TFEa may cover (e.g., completely cover) the first capping layer CPL1 in the display area DA to cover the first light emitting element, the second light emitting element, and the third light emitting element. The organic encapsulation layer TFEb may be disposed on the lower inorganic encapsulation layer TFEa to cover (e.g., completely cover) the lower inorganic encapsulation layer TFEa. The upper inorganic encapsulation layer TFEc may be disposed on the organic encapsulation layer TFEb to cover (e.g., completely cover) the organic encapsulation layer TFEb.

In an embodiment, each of the lower inorganic encapsulation layer TFEa and the upper inorganic encapsulation layer TFEc may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiOₓN_{y}), lithium fluoride, or the like, but embodiment are not limited thereto.

In an embodiment, the organic encapsulation layer TFEb may be formed of acrylic resin, methacrylic resin, polyisoprene, vinyl resin, epoxy resin, urethane resin, cellulose resin, perylene resin or the like, but embodiment are not limited thereto.

Hereinafter, the light transmitting portion 300 will be described with reference to FIG. 5.

The light transmitting portion 300 may have a structure in which the second substrate 310, the color filter layer 320, the second capping layer CPL2, a light transmitting member, the bank pattern layer BK, and the third capping layer CPL3 are sequentially stacked on another side of the third direction DR3.

The second substrate 310 of the light transmitting portion 300 may function as a base of the light transmitting portion 300. The second substrate 310 may be made of a light transmitting material. The second substrate 310 may be a glass substrate or a plastic substrate.

In case that the second substrate 310 is a plastic substrate, the second substrate 310 may have flexibility. In an embodiment, in case that the second substrate 310 is a plastic substrate, the second substrate 310 may include polyimide, but embodiment are not limited thereto. As described above, since the light emitting portion 100 and the light transmitting portion 300 face each other in the third direction DR3, the first substrate 110 of the light emitting portion 100 and the second substrate 310 of the light transmitting portion 300 may face each other in the third direction DR3.

The color filter layer 320 of the light transmitting portion 300 may be disposed on another side of the second substrate 310 in the third direction DR3, e.g., between the second substrate 310 and the light emitting portion 100. The color filter layer 320 may include a filtering pattern area and a light blocking pattern portion BM. The light blocking pattern portion BM may surround the filtering pattern area. The filtering pattern of the color filter layer 320 may define a transmission area of the light transmitting portion 300, and the light blocking pattern portion BM may define the light blocking area BA of the light transmitting portion 300.

As illustrated in FIG. 5, the color filter layer 320 may include a first color filter 321, a second color filter 322, and a third color filter 323. The first color filter 321 may absorb both the second light and the third light except for the first light, the second color filter 322 may absorb both the first light and the third light except for the second light, and the third color filter 323 may absorb both the first light and the second light except for the third light. For example, the first color filter 321 may transmit the first light, the second color filter 322 may transmit the second light, and the third color filter 323 may transmit the third light.

In an embodiment, the first color filter 321 may be a blue color filter and may include a blue colorant. In the disclosure, the colorant may include a dye and a pigment. The first color filter 321 may include a base resin and the blue colorant may be dispersed in the base resin. In an embodiment, the second color filter 322 may be a green color filter and may include a green colorant. The second color filter 322 may include a base resin and the green colorant may be dispersed in the base resin. In an embodiment, the third color filter 323 may be a red color filter and may include a red colorant. The third color filter 323 may include a base resin and the red colorant may be dispersed in the base resin.

The first color filter 321 may include a first filtering pattern area 321a and a first blocking pattern area 321b surrounding the first filtering pattern area 321a, the second color filter 322 may include a second filtering pattern area 322a and a second blocking pattern area 322b surrounding the second filtering pattern area 322a, and the third color filter 323 may include a third filtering pattern area 323a and a third blocking pattern area 323b surrounding the third filtering pattern area 323a. For example, the first filtering pattern area 321a of the first color filter 321 may overlap the first transmission area TA_1. The first blocking pattern area 321b of the first color filter 321 may surround the first filtering pattern area 321a overlapping the first transmission area TA_1, and may overlap the light blocking area BA. The first blocking pattern area 321b of the first color filter 321 may not overlap the second transmission area TA_2 and the third transmission area TA_3. The second filtering pattern area 322a of the second color filter 322 may overlap the second transmission area TA_2. The second blocking pattern area 322b of the second color filter 322 may surround the second filtering pattern area 322a overlapping the second transmission area TA_2, and may overlap the light blocking area BA. The second blocking pattern area 322b of the second color filter 322 may not overlap the first transmission area TA_1 and the third transmission area TA_3. The third filtering pattern area 323a of the third color filter 323 may overlap the third transmission area TA_3. The third blocking pattern area 323b of the third color filter 323 may surround the third filtering pattern area 323a overlapping the third transmission area TA_3, and may overlap the light blocking area BA. The third blocking pattern area 323b of the third color filter 323 may not overlap the first transmission area TA_1 and the second transmission area TA_2. For example, the filtering pattern area of the color filter layer 320 may include the first filtering pattern area 321a of the first color filter 321, the second filtering pattern area 322a of the second color filter 322, and the third filtering pattern area 323a of the third color filter 323. The light blocking pattern portion BM may have a structure in which the first blocking pattern area 321b of the first color filter 321, the second blocking pattern area 322b of the second color filter 322, and the third blocking pattern area 323b of the third color filter 323 are stacked with each other.

The first filtering pattern area 321a of the first color filter 321 may function as a blocking filter that blocks red light and green light. For example, the first filtering pattern area 321a may selectively transmit the first light (e.g., blue light) and block or absorb the second light (e.g., green light) and the third color light (e.g., red light).

The second filtering pattern area 322a of the second color filter 322 may function as a blocking filter that blocks blue light and red light. For example, the second filtering pattern area 322a may selectively transmit the second light (e.g., green light) and block or absorb the first light (e.g., blue light) and the third light (e.g., red light).

The third filtering pattern area 323a of the third color filter 323 may function as a blocking filter that blocks blue light and green light. For example, the third filtering pattern area 323a may selectively transmit the third light (e.g., red light) and block or absorb the first light (e.g., blue light) and the second light (e.g., green light).

In an embodiment, the light blocking pattern portion BM may have a structure in which the first blocking pattern area 321b, the third blocking pattern area 323b, and the second blocking pattern area 322b are sequentially stacked on another side of the third direction DR3, but embodiments are not limited thereto. For example, the light blocking pattern portion BM may not be constituted with the color filters 321, 322, and 323 described above, but may be formed as a separate organic light blocking material through coating and exposure processes of the organic light blocking material, and the like. Hereinafter, for simplicity of description, description will be made focusing on the fact that the light blocking pattern has a structure in which the first blocking pattern area 321b, the third blocking pattern area 323b, and the second blocking pattern area 322b are sequentially stacked on another side of the third direction DR3. The light blocking pattern portion BM may absorb all of the first light, the second light, and the third light through the above-described configuration.

A low refractive layer LR may be disposed on the color filter layer 320. The low refractive layer LR may have a lower refractive index than a light transmitting layer TPL, a first wavelength conversion layer WCL1, and a second wavelength conversion layer WCL2, which will be described later, and thus may function to recycle light by inducing total reflection of light traveling from the light transmitting layer TPL, the first wavelength conversion layer WCL1, and the second wavelength conversion layer WCL2 to the low refractive layer LR.

In an embodiment, the refractive index of the low refractive layer LR may be in a range of about 1.10 to about 1.30. In case that the above range is satisfied, total reflection of light may sufficiently occur and light loss may be reduced.

The refractive index described in the disclosure may be measured using an optical measuring instrument such as an ellipsometer, a spectral reflectometer, or the like. The ellipsometer may measure the refractive index by measuring the amount of change in polarization of incident light and reflected light with respect to the inorganic layer and by calculating the thickness and complex refractive index of the inorganic layer. The spectral reflectometer may measure the refractive index of the inorganic layer by comparing the intensity of light acquired by changing the wavelength. The refractive index may be a value measured at room temperature and normal pressure.

Further, the low refractive layer LR may function to provide a flat surface by compensating for stepped portions generated by the blocking pattern areas 321b, 322b, and 323b of the color filter layer 320. Accordingly, the second capping layer CPL2 disposed on the low refractive layer LR may be formed to be substantially flat. The thickness of the low refractive layer LR in the light blocking area BA may be different from the thickness in the transmission areas TA_1, TA_2, and TA_3, and the thickness of the low refractive layer LR in the light blocking area BA may be smaller than the thickness in the transmission areas TA_1, TA_2, and TA_3.

The second capping layer CPL2 of the light transmitting portion 300 may be disposed on a surface of the low refractive layer LR to cover the low refractive layer LR. The second capping layer CPL2 may prevent impurities such as moisture or air from the outside from permeating into the low refractive layer LR or the color filter layer 320 and from damaging or contaminating the filtering pattern area and the light blocking pattern portion BM of the low refractive layer LR and the color filter layer 320.

The second capping layer CPL2 may include an inorganic material. As will be described later, the second capping layer CPL2 may be formed as a single layer or multiple layers.

The refractive index of the second capping layer CPL2 may be greater than the refractive index of the low refractive layer LR. In an embodiment, the refractive index of the second capping layer CPL2 may be greater than the refractive index of the low refractive layer LR by about 0.30 to about 0.60. In case that the refractive index difference is within the above range, total reflection in the low refractive layer LR may occur well, and light may be recycled. In an embodiment, the refractive index of the second capping layer CPL2 may be in a range of about 1.40 to about 1.70.

The second capping layer CPL2 may include a first surface CPL2_S1 facing the low refractive layer LR and a second surface CPL2_S2 opposite to the first surface CPL2_S1.

The second surface CPL2_S2 of the second capping layer CPL2 in the first emission area ELA_1 or the first transmission area TA_1 may include a capping concave-convex pattern CPL2_P. The second surface CPL2_S2 of the second capping layer CPL2 in the second emission area ELA_2 or the second transmission area TA_2 may be substantially flat and may not include a concave-convex pattern. The second surface CPL2_S2 of the second capping layer CPL2 in the third emission area ELA_3 or the third transmission area TA_3 may be substantially flat and may not include a concave-convex pattern. For example, the second surface CPL2_S2 of the second capping layer CPL2 may include the capping concave-convex pattern CPL2_P only for the first transmission area TA_1 through which blue light is transmitted, and the second surface CPL2_S2 of the second capping layer CPL2 may not have the capping concave-convex pattern CPL2_P for the second transmission area TA_2 through which green light is transmitted and the third transmission area TA_3 through which red light is transmitted and may be substantially flat.

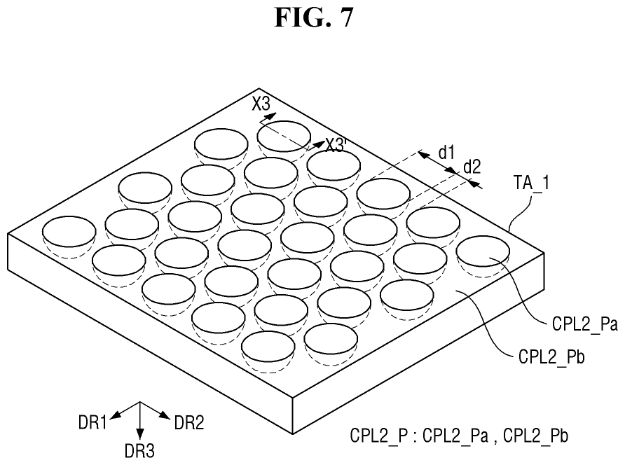

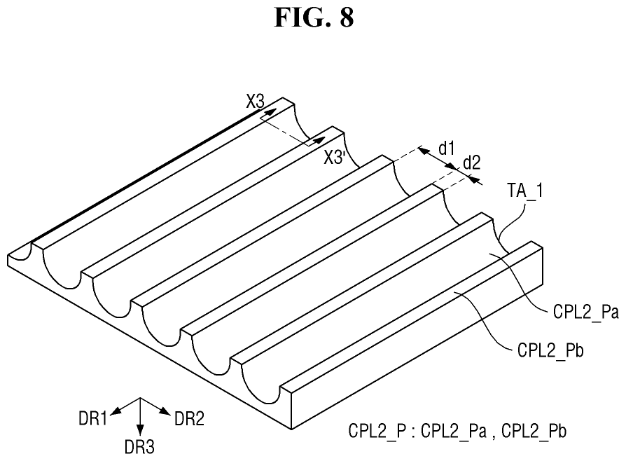

In an embodiment, the capping concave-convex pattern CPL2_P may be a plurality of island-like patterns separated from each other, as illustrated in FIG. 7. Each island-like pattern may have a dot shape. FIG. 7 illustrates that each dot has a circular cross section of the same diameter in plan view, but each dot may have a circular or elliptical cross section of a different diameter. In another embodiment, the capping concave-convex pattern CPL2_P may be an extended linear pattern or a linear pattern extending in a direction (e.g., first direction DR1). Although a linear pattern in the form of a straight line is illustrated in FIG. 8, the linear pattern may include a curved shape.

The capping concave-convex pattern CPL2_P may include depressed portions CPL2_Pa and flat portions CPL2_Pb. The flat portion CPL2_Pb may be the same surface as the second surface CPL2_S2 of the second capping layer CPL2 in the second emission area ELA_2, the second transmission area TA_2, the third emission area ELA_3, or the third transmission area TA_3. The depressed portion CPL2_Pa may be a recess pattern from the flat portion CPL2_Pb in the thickness direction DR3.

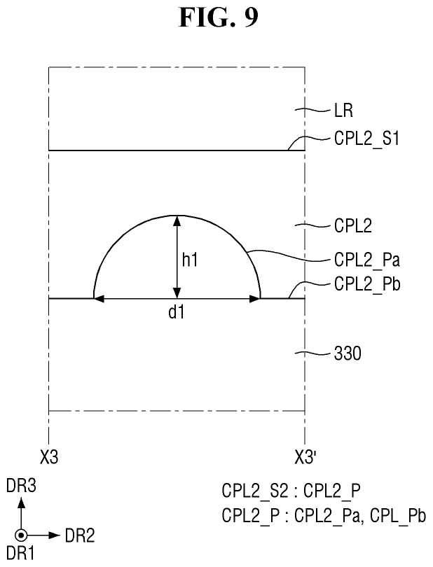

FIG. 9 is an enlarged schematic view of a cross section taken along line X3-X3′ of FIGS. 7 and 8, e.g., the depressed portion CPL2_Pa. FIG. 9 illustrates not only the second capping layer CPL2, but also the lower light transmitting layer TPL and the low refractive layer LR.

The depressed portion CPL2_Pa of the capping concave-convex pattern CPL2_P may have a concave-shaped cross section such as a half-round, half-ellipse, or segment of a circle shape. For example, in case that the capping concave-convex pattern CLP2_P is an island-like pattern, the depressed portion CPL2_Pa may have a three-dimensional outer surface of a hemisphere, hemiellipsoid, or dome shape. In case that the depressed portion CPL2_Pa has a pointed cross section like a horn, it may be difficult to scatter light in a random direction. In case that the depressed portion CPL2_Pa has a round cross section, light may be scattered and spread widely.

The depressed portion CPL2_Pa of the capping concave-convex pattern CPL2_P may have a maximum length depressed from the flat portion CPL2_Pb as a depth hi of the depressed portion CPL2_Pa in cross-sectional view. In an embodiment, the depth hi of the depressed portion CPL2_Pa may be greater than or equal to about 0.1 m. In another embodiment, the depth hi of the depressed portion CPL2_Pa may be in a range of about 0.2 m to about 1 m. In the case of the above range, it is possible to increase light efficiency with maintaining an excellent scattering effect.

The depressed portion CPL2_Pa of the capping concave-convex pattern CPL2_P may have the length from an end portion of the depressed portion CPL2_Pa meeting the flat portion CPL2_Pb to another end portion of the depressed portion CPL2_Pa opposite to the end portion, in cross-sectional view, as a width dl of the depressed portion CPL2_Pa. The width dl of the depressed portion CPL2_Pa may mean a distance between two points within a depressed portion. In an embodiment, the width dl of the depressed portion CPL2_Pa may be greater than or equal to about 3 m. In another embodiment, the width dl of the depressed portion CPL2_Pa may be in a range of about 4 m to about 10 m. In the case of the above range, it is possible to increase light efficiency with maintaining an excellent scattering effect.

In an embodiment, a distance d2 between the adjacent depressed portions of the capping concave-convex pattern CPL2_P in cross-sectional view may be about 1.5 μm or more. In another embodiment, the distance d2 between the adjacent depressed portions may be about 2.5 μm to about 10 μm. In the case of the above range, it is possible to increase light efficiency with maintaining an excellent scattering effect.

The bank pattern layer BK of the light transmitting portion 300 may be disposed on the second surface CPL_S2 of the second capping layer CPL2 with reference to FIG. 5 and form a space accommodating a light transmitting member to be described later. A plurality of spaces accommodating the light transmitting member may be configured, and may be spaced apart from each other. For example, the bank pattern layer BK may function to partition a space in which a light transmitting member, which will be described later, is disposed. The bank pattern layer BK may be in contact with (e.g., in direct contact with) the second surface CPL_S2 of the second capping layer CPL2. The bank pattern layer BK may surround a light transmitting member to be described later in plan view. The bank pattern layer BK may overlap the non-emission area NELA of the light emitting portion 100 and the light blocking area BA of the light transmitting portion 300. The bank pattern layer BK may not overlap the emission areas ELA_1, ELA_2, and ELA_3 of the light emitting portion 100 and the transmission areas TA_1, TA_2, and TA_3 of the light transmitting portion 300.

In an embodiment, the bank pattern layer BK may include an organic material having photocurability or an organic material having photocurability and including a light blocking material, but embodiment are not limited thereto.

The light transmitting member of the light transmitting portion 300 may be disposed on the second surface CPL_S2 of the second capping layer CPL2 exposed by the separation space of the bank pattern layer BK. The light transmitting member may include the light transmitting layer TPL overlapping the first transmission area TA_1, the first wavelength conversion layer WCL1 overlapping the second transmission area TA_2, and the second wavelength conversion layer WCL2 overlapping the third transmission area TA_3. For example, the light transmitting layer TPL, the first wavelength conversion layer WCL1 and the second wavelength conversion layer WCL2 may be referred to as a wavelength conversion layer or a wavelength conversion material layer in the claims.

The light transmitting layer TPL may be disposed in the space partitioned by the bank pattern layer BK, and may overlap the first emission area ELA_1 and the first transmission area TA_1 in the third direction DR3.

The light transmitting layer TPL may have a light transmission pattern that transmits incident light. For example, as described above, the emission light LE provided from the first light emitting element may be blue light and may pass through the light transmitting layer TPL and the first filtering pattern area 321a of the first color filter 321 to be emitted to the outside of the display device 1. For example, first emission light L1 passing through the first transmission area TA_1 in the first emission area ELA_1 and emitted to the outside may be blue light.

The light transmitting layer TPL may include a base resin 330. The base resin 330 may be made of an organic material having high light transmittance. In an embodiment, the base resin 330 may include an organic material such as epoxy resin, acrylic resin, silicone resin, cardo resin, or imide resin, but embodiment are not limited thereto.

The light transmitting layer TPL may be in contact with (e.g., in direct contact with) the second capping layer CPL2 and the bank pattern layer BK. A surface of the light transmitting layer TPL may include a concave-convex pattern that is in contact with the capping concave-convex pattern CPL2_P of the second capping layer CPL2 and engaged with the capping concave-convex pattern CPL2_P. The surface of the light transmitting layer TPL may be a top surface (or upper surface) of the light transmitting layer TPL in FIG. 5.

In case that the light transmitting layer TPL includes a light scatterer, light may be scattered in a random direction regardless of an incident direction of light passing through the first transmission area TA_1. In case that the total content of the light scatterer included in the light transmitting layer TPL is high, the front-side luminance ratio may be high, but the light efficiency is reduced. Further, an ink having the high content of the light scatterer may have a high viscosity, so that a tact time may be increased during a process.

In case that the light transmitting layer TPL and the second capping layer CPL2 have concave-convex patterns, light passing through the first transmission area TA_1 may be scattered with passing through the concave-convex pattern. Side visibility may be improved by scattering light although the light transmitting layer TPL includes a light scatterer with a low content or does not include a light scatterer. Accordingly, the display device 1 having the capping concave-convex pattern CPL2_P may have both high light efficiency and high luminance, and a fabrication process time may be reduced. In an embodiment, the light transmitting layer TPL may not include a light scatterer. The content of TiO₂ included in the light transmitting layer TPL may be about 0%.

Further, the concave-convex pattern between the light transmitting layer TPL and the second capping layer CPL2 may increase a contact area and thus may increase adhesive strength between the light transmitting layer TPL and the second capping layer CPL2.

The light transmitting layer TPL may have a refractive index equal to or similar to the refractive index of the second capping layer CPL2. In an embodiment, the refractive index of the light transmitting layer TPL may be in a range of about 1.40 to about 1.70. In an embodiment, the refractive index of the light transmitting layer TPL may be greater than the refractive index of the low refractive layer LR, and the difference between the refractive index of the light transmitting layer TPL and the refractive index of the low refractive layer LR may be in a range of about 0.30 to about 0.60. In case that the second capping layer CPL2 does not have a light scatterer, the refractive index of the second capping layer CPL2 and the refractive index of the base resin 330 may be the same as each other.

The first wavelength conversion layer WCL1 may be disposed in a space partitioned by the bank pattern layer BK, and may overlap the second emission area ELA_2 and the second transmission area TA_2 in the third direction DR3. The first wavelength conversion layer WCL1 may be in contact with (e.g., in direct contact with) the second capping layer CPL2 and the bank pattern layer BK. A surface of the first wavelength conversion layer WCL1 may be in contact with the second surface CPL2_S2 of the second capping layer CPL2, and the surface of the first wavelength conversion layer WCL1 may be substantially flat. The surface of the first wavelength conversion layer WCL1 may be the top surface (or upper surface) of the first wavelength conversion layer WCL1 in FIG. 5.

The first wavelength conversion layer WCL1 may be a wavelength conversion pattern layer that converts or shifts the peak wavelength of incident light into light of another specific peak wavelength to emit the light. For example, as described above, the emission light LE provided from the second light emitting element may be blue light and may pass through the first wavelength conversion layer WCL1 and the second filtering pattern area 322a of the second color filter 322 and be converted into green light having a peak wavelength in a range of about 510 nm to about 550 nm to be emitted to the outside of the display device 1. For example, second emission light L2 passing through the second transmission area TA_2 in the second emission area ELA_2 and emitted to the outside may be green light.

The first wavelength conversion layer WCL1 may include a base resin 330, a light scatterer 331 dispersedly disposed within the base resin 330, and a first wavelength shifter 332 dispersedly disposed within the base resin 330.

The light scatterer 331 may have a refractive index different from that of the base resin 330 and form an optical interface with the base resin 330. The light scatterer 331 may be a light scattering particle. The light scatterer 331 may scatter light in a random direction irrespective of the incident direction of incident light, without substantially converting the wavelength of the light passing through the second transmission area TA_2.

The light scatterer 331 may be a material that scatters at least a part of transmitted light, and may include metal oxide particles or organic particles. In an embodiment, the light scatterer 331 may include titanium oxide (TiO₂), zirconium oxide (ZrO₂), aluminum oxide (Al₂O₃), indium oxide (In₂O₃), zinc oxide (ZnO), tin oxide (SnO₂), and the like as a metal oxide, and may include an acrylic resin or a urethane-based resin, and the like as the organic particles, but embodiment are not limited thereto.

The first wavelength shifter 332 may convert or shift the peak wavelength of incident light to another specific peak wavelength. The first wavelength shifter 332 may convert the emission light LE, which is blue light provided from the second light emitting element, into green light having a single peak wavelength in a range of about 510 nm to about 550 nm and emit the light.

In an embodiment, the first wavelength shifter 332 may be a quantum dot, a quantum rod, or a fluorescent substance, but embodiment are not limited thereto. Hereinafter, for simplicity of description, the first wavelength shifter 332 will be described as a quantum dot.

The quantum dot may be a particulate material that emits light of a specific color in case that an electron transitions from a conduction band to a valence band. The quantum dot may be a semiconductor nanocrystal material. The quantum dot may have a specific band gap according to its composition and size. Thus, the quantum dot may absorb light and emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The group II-VI compound may be selected from the group consisting of binary compounds, ternary compounds, and quaternary compounds, wherein the binary compounds are selected from the group consisting of CdSe, CdTe, ZnS, ZnSe, ZnTe, ZnO, HgS, HgSe, HgTe, MgSe, MgS and mixtures thereof, the ternary compounds are selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and the quaternary compounds are selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be selected from the group consisting of binary compounds, ternary compounds, and quaternary compounds, wherein the binary compounds are selected from the group consisting of GaN, GaP, GaAs, GaSb, AlN, AlP, AlAs, AlSb, InN, InP, InAs, InSb and mixtures thereof, the ternary compounds are selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and mixtures thereof, and the quaternary compounds are selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compound may be selected from the group consisting of binary compounds, ternary compounds, and quaternary compounds, wherein the binary compounds are selected from the group consisting of SnS, SnSe, SnTe, PbS, PbSe, PbTe and mixtures thereof, the ternary compounds are selected from the group consisting of SnSeS, SnSeTe, SnSTe, PbSeS, PbSeTe, PbSTe, SnPbS, SnPbSe, SnPbTe and mixtures thereof, and the quaternary compounds are selected from the group consisting of SnPbSSe, SnPbSeTe, SnPbSTe and mixtures thereof. The group IV element may be selected from the group consisting of Si, Ge and mixtures thereof. The group IV compound may be a binary compound selected from the group consisting of SiC, SiGe and mixtures thereof.

For example, the binary compound, the tertiary compound or the quaternary compound may be included in particles at a uniform concentration, or may be included in the same particle divided into states where concentration distributions are partially different. Further, the particles may have a core/shell structure in which a quantum dot surrounds another quantum dot. An interface between the core and the shell may have a concentration gradient in which the concentration of elements included in the shell decreases toward the center.

In an embodiment, the quantum dot may have a core-shell structure including a core including the nanocrystal described above and a shell surrounding the core. The shell of the quantum dot may function as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of elements included in the shell decreases toward the center. Examples of the shell of the quantum dot may include a metal or non-metal oxide, a semiconductor compound, and a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, but embodiments are not limited thereto.

For example, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but embodiments are not limited thereto.

The light emitted from the first wavelength shifter 332 may have a full width of half maximum (FWHM) of the emission wavelength spectrum, which is about 45 nm or less, about 40 nm or less, or about 30 nm or less. Thus, the purity and reproducibility of colors displayed by the display device 1 may be further improved. For example, the light emitted from the first wavelength shifter 332 may be emitted in various directions regardless of the incident direction of incident light. Accordingly, side visibility of the second color displayed in the second transmission area TA_2 may be improved.

Some of the emission light LE provided from the second light emitting element may pass through the first wavelength conversion layer WCL1 and be emitted without being converted into green light by the first wavelength shifter 332. Among the emission light LE, a component whose wavelength may not be converted by the first wavelength conversion layer WCL1 and which is incident on the second filtering pattern area 322a of the second color filter 322 may be blocked by the second filtering pattern area 322a. Among the emission light LE, green light converted by the first wavelength conversion layer WCL1 may pass through the second filtering pattern area 322a and may be emitted to the outside. For example, the second emission light L2 emitted to the outside of the display device 1 through the second transmission area TA_2 may be green light.

The second wavelength conversion layer WCL2 may be disposed in a space partitioned by the bank pattern layer BK, and may overlap the third emission area ELA_3 and the third transmission area TA_3 in the third direction DR3. The second wavelength conversion layer WCL2 may be in contact with (e.g., in direct contact with) the second capping layer CPL2 and the bank pattern layer BK.

The second wavelength conversion layer WCL2 may be a wavelength conversion pattern layer that converts or shifts the peak wavelength of incident light into light of another specific peak wavelength to emit the light. For example, as described above, the emission light LE provided from the second light emitting element may be blue light and may pass through the second wavelength conversion layer WCL2 and the third filtering pattern area 323a of the third color filter 323 and be converted into red light having a peak wavelength in a range of about 610 nm to about 650 nm to be emitted to the outside of the display device 1. For example, the third emission light L3 that passes through the third transmission area TA_3 in the third emission area ELA_3 and emitted to the outside may be red light.

The second wavelength conversion layer WCL2 may include the base resin 330, the light scatterer 331 dispersedly disposed within the base resin 330, and a second wavelength shifter 333 dispersedly disposed within the base resin 330.

The second wavelength shifter 333 may convert or shift the peak wavelength of incident light to another specific peak wavelength. The second wavelength shifter 333 may convert the emission light LE, which is blue light provided from the third light emitting element, into red light having a single peak wavelength in a range of about 610 nm to about 650 nm and emit the light. The second wavelength shifter 333 may convert not only blue light but also green light into red light and emit the red light. In an embodiment, the second wavelength shifter 333 may be a quantum dot, a quantum rod, or a fluorescent substance, but embodiment are not limited thereto. The case where the second wavelength shifter 333 is a quantum dot has substantially the same configuration as the case where the first wavelength shifter 332 is a quantum dot as described above, and thus a description thereof will be omitted for descriptive convenience.

Some of the emission light LE provided from the third light emitting element may pass through the first wavelength conversion layer WCL1 and be emitted without being converted into red light by the second wavelength shifter 333. Among the emission light LE, a component whose wavelength may not be converted by the second wavelength conversion layer WCL2 and may be incident on the third filtering pattern area 323a of the third color filter 323 may be blocked by the third filtering pattern area 323a. Among the emission light LE, red light converted by the second wavelength conversion layer WCL2 may pass through the third filtering pattern area 323a and may be emitted to the outside. For example, the third emission light L3 emitted to the outside of the display device 1 through the third transmission area TA_3 may be red light.

The third capping layer CPL3 of the light transmitting portion 300 may be disposed on the bank pattern layer BK, the light transmitting layer TPL, the first wavelength conversion layer WCL1, and the second wavelength conversion layer WCL2 and may function to prevent impurities such as moisture or air from the outside from permeating and damaging or contaminating the light transmitting layer TPL, the first wavelength conversion layer WCL1, and the second wavelength conversion layer WCL2. The third capping layer CPL3 may cover the light transmitting layer TPL, the first wavelength conversion layer WCL1, and the second wavelength conversion layer WCL2.

As described above, the filling portion 500 may be interposed between the light emitting portion 100 and the light transmitting portion 300 to fill the space between the light emitting portion 100 and the light transmitting portion 300. In an embodiment, the filling portion 500 may be in contact with (e.g., in direct contact with) the upper inorganic encapsulation layer TFEc of the thin film encapsulation layer TFE of the light emitting portion 100 and the third capping layer CPL3 of the light transmitting portion 300, but embodiment are not limited thereto.

In an embodiment, the filling portion 500 may be made of a material having an extinction coefficient of substantially zero. There may be a correlation between a refractive index and an extinction coefficient, and as the refractive index decreases, the extinction coefficient may also decrease. For example, in case that the refractive index is about 1.7 or less, the extinction coefficient may substantially approach to about zero. In an embodiment, the filling portion 500 may be made of a material having a refractive index of about 1.7 or less, and thus it is possible to prevent or minimize light provided from the self-light emitting element from being absorbed with passing through the filling portion 500. In an embodiment, the filling portion 500 may be made of an organic material having a refractive index of about 1.4 to about 1.6.

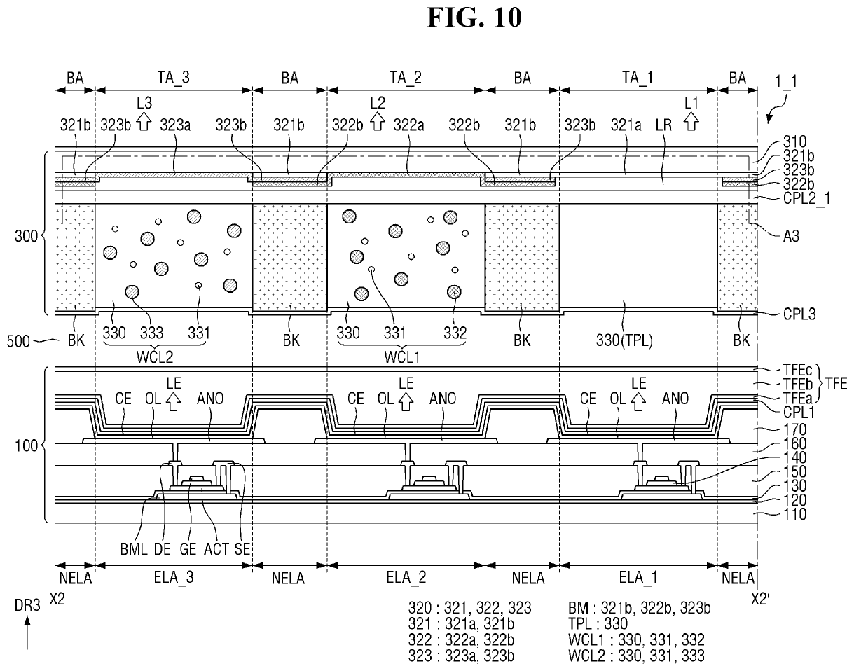

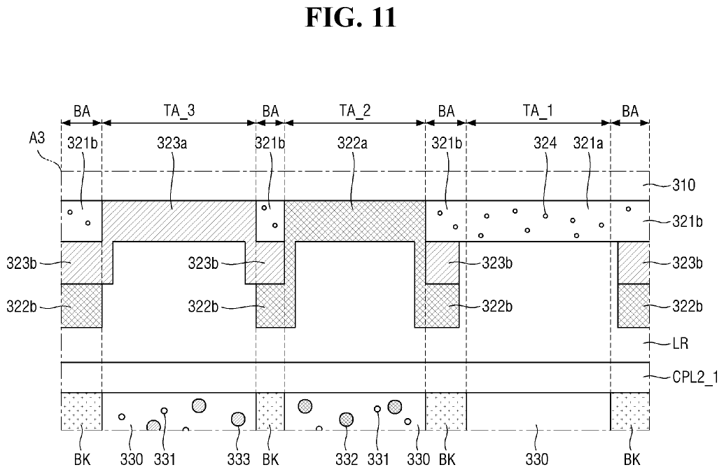

FIG. 10 is a schematic cross-sectional view of a display device 1_1 according to another embodiment. FIG. 11 is an enlarged schematic view of an area A3 of FIG. 10. Compared to FIG. 5, there are differences in FIGS. 10 and 11 in that the second surface CPL2_S2 of a second capping layer CPL2_1 in the first transmission area TA_1 is substantially flat and the first color filter 321 includes a light scatterer 324.

The light transmitting layer TPL may be fabricated through an inkjet process, and at this time, the viscosity and thickness of the ink may be important process variables. In case that the light transmitting layer TPL includes a high content of the light scatterer, the viscosity of the ink increases, so that it may be difficult to control the process. In case that the content of the light scatterer is fixed and the thickness of the ink is increased, the tact time may be increased. For example, the color filter may be fabricated by application or deposition, which is not affected by the content of the light scatterer compared to the inkjet process. In case that the first color filter 321 other than the light transmitting layer TPL includes a light scatterer, process control may be facilitated and a scattering effect may be obtained.

The description of the light scatterer 331 of the first wavelength conversion layer WCL1 described above may be applied to the light scatterer 324 included in the first color filter 321. The light scatterer 324 of the first color filter 321 may be the same as or different from the light scatterer 331 of the first wavelength conversion layer WCL1.

The first wavelength conversion layer WCL1 and the second wavelength conversion layer WCL2 may include the light scatterer 331, and the light transmitting layer TPL, the second color filter 322, and the third color filter 323 may not include a light scatterer. A content of TiO₂ included in the light transmitting layer TPL, the second color filter 322, and the third color filter 323 may be about 0%.

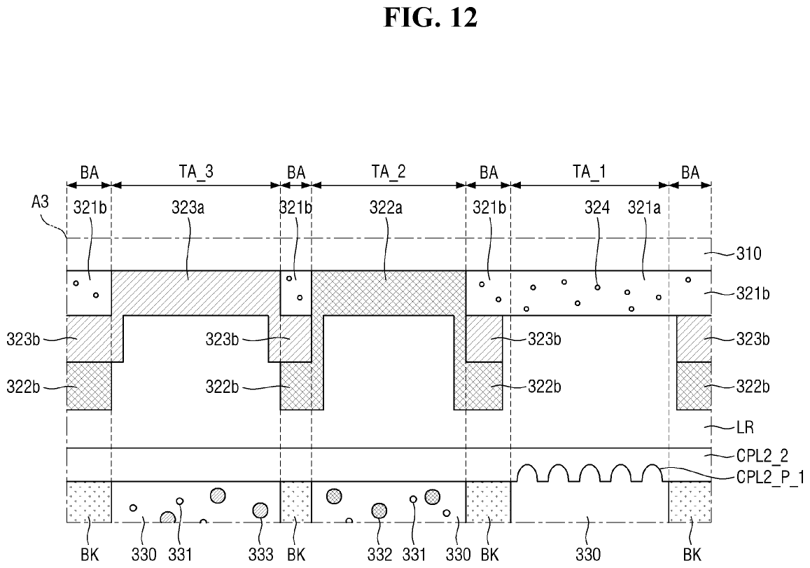

FIG. 12 is a schematic cross-sectional view of a display device according to still another embodiment. Compared to FIG. 11, it is different in that the second surface CPL2_S2 of a second capping layer CPL2_2 in the first transmission area TA_1 includes a capping concave-convex pattern CPL2_P_1. As described above, since the second surface CPL2_S2 of the second capping layer CPL2_2 includes the capping concave-convex pattern CPL2_P_1, the display device may have an excellent scattering effect and high light efficiency.

Hereinafter, a method for fabrication of the display device 1 will be described.

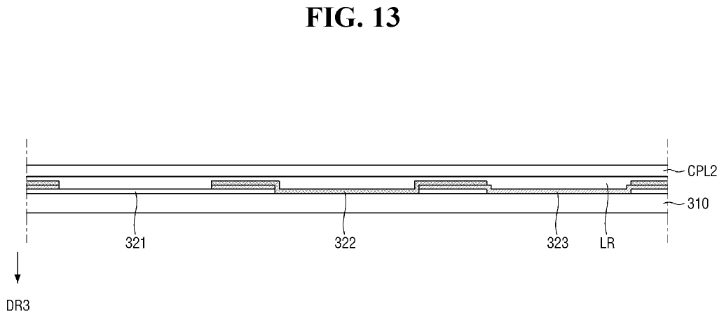

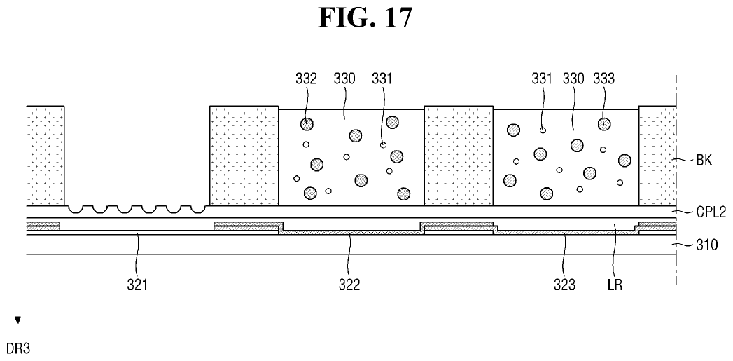

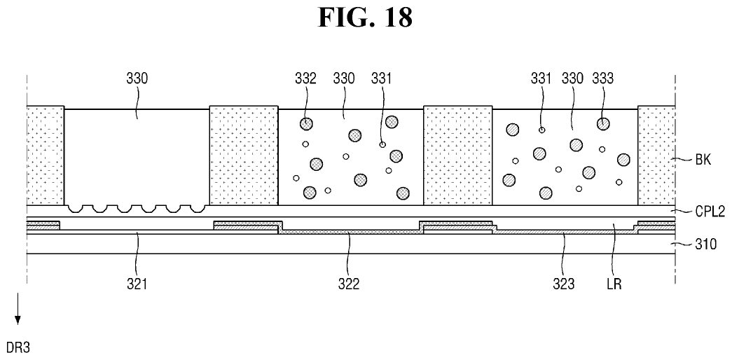

FIGS. 13, 14, 15, 16, 17, 18, 19, and 20 are schematic diagrams for explaining a process of fabricating a second capping layer of a display device according to an embodiment.

First, referring to FIG. 13, the color filter layer 320 may be formed on the second substrate 310 of the display device 1 according to an embodiment, and the low refractive layer LR may be formed on the color filter layer 320.

As described above, in the color filter layer 320, the first color filter 321, the third color filter 323, and the second color filter 322 may be sequentially stacked with each other. The first color filter 321 may be formed to overlap the first transmission area TA_1 and the light blocking area BA, but may be formed not to overlap the second transmission area TA_2 and the third transmission area TA_3. The third color filter 323 may be formed to overlap the third transmission area TA_3 and the light blocking area BA, but may be formed not to overlap the first transmission area TA_1 and the second transmission area TA_2. The second color filter 322 may be formed to overlap the second transmission area TA_2 and the light blocking area BA, but may be formed not to overlap the first transmission area TA_1 and the third transmission area TA_3. In an embodiment, each of the color filter and the low refractive layer LR may be formed by a deposition process. In an embodiment, the first color filter 321 may be formed using a material that includes the light scatterer 324, the second color filter 322 may be formed using a material that does not include the light scatterer 324, and the third color filter 323 may be formed using a material that does not include the light scatterer 324.

For example, a second capping layer CPL2 may be formed on the low refractive layer LR. For example, the process of forming the second capping layer CPL2 may be a deposition process using plasma.

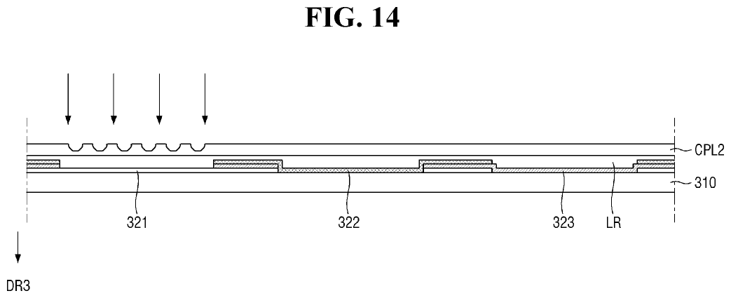

Referring to FIG. 14, in the first transmission area TA_1 to the third transmission area TA_3, the capping concave-convex pattern CPL2_P may be formed on the top surface (or upper surface) of the second capping layer CPL2 only in the first transmission area TA_1. The capping concave-convex pattern CPL2_P may be formed by dry etching and photo processes.

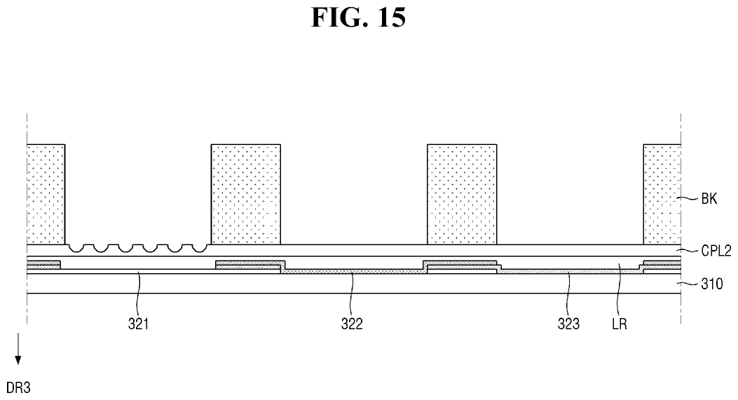

Referring to FIG. 15, the bank pattern layer BK may be formed to overlap the light blocking area BA between the spaced transmission areas.

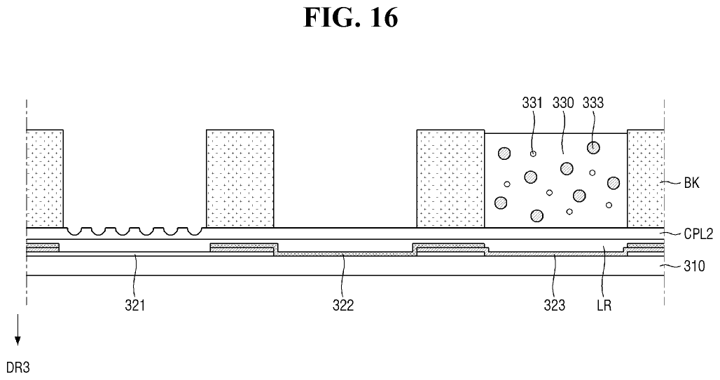

Referring to FIGS. 16, 17, and 18, the light transmitting layer TPL may be formed in the first transmission area TA_1, the first wavelength conversion layer WCL1 may be formed in the second transmission area TA_2, and the second wavelength conversion layer WCL2 may be formed in the third transmission area TA_3. In an embodiment, the ink may be ejected to the transmission area TA_2 by an inkjet method using a nozzle. FIGS. 16, 17, and 18 illustrate that the second wavelength conversion layer WCL2, the first wavelength conversion layer WCL1, and the light transmitting layer TPL are sequentially formed, but embodiments are not limited thereto. The light transmitting layer TPL, the first wavelength conversion layer WCL1, and the second wavelength conversion layer WCL2 may be formed in this order, or the order may be partially changed. The light transmitting layer TPL, the first wavelength conversion layer WCL1 and the second wavelength conversion layer WCL2 may be formed to have a height lower than the top surface (or upper surface) of the bank pattern layer BK.

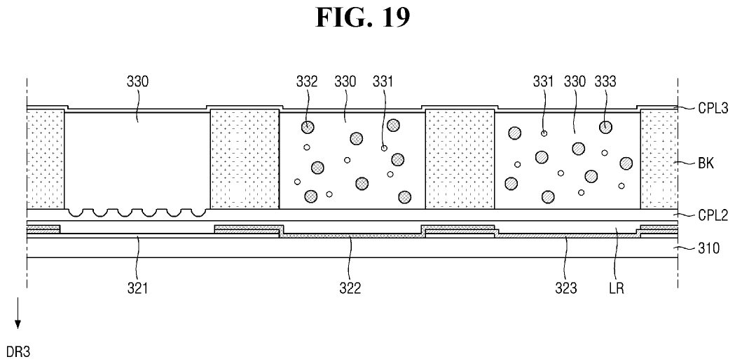

Referring to FIG. 19, the third capping layer CPL3 may be formed on the light transmitting layer TPL, the first wavelength conversion layer WCL1, the second wavelength conversion layer WCL2, and the bank pattern layer BK.

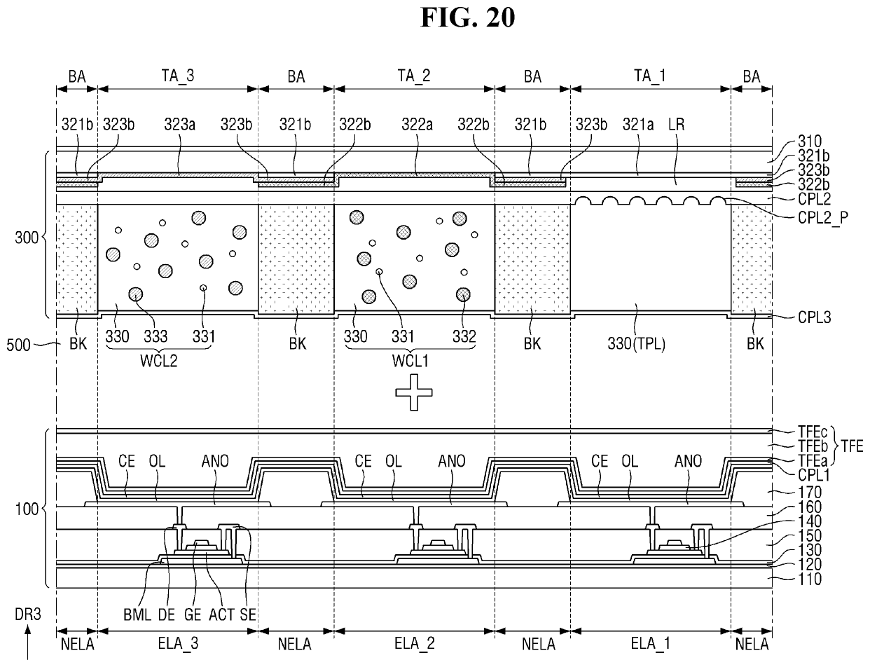

Referring to FIG. 20, the light emitting portion 100 equipped with light emitting elements and circuits, the filling portion 500, and the sealing member 700 may be additionally prepared, and the light emitting portion 100 and the light transmitting portion 300 may be bonded together via the filling portion 500 to fabricate the display device 1.

In concluding the detailed description, those skilled in the art will appreciate that many variations and modifications can be made to the embodiments without substantially departing from the principles of the disclosure. Therefore, the disclosed embodiments of the invention are used in a generic and descriptive sense only and not for purposes of limitation.

What is claimed is:

1. A display device comprising:
a first substrate comprising a first emission area and a second emission area;
a first light emitting element overlapping the first emission area and a second light emitting element overlapping the second emission area, the first and second light emitting elements disposed on the first substrate;
a light transmitting layer disposed on the first light emitting element;
a first wavelength conversion layer disposed on the second light emitting element;
a capping layer disposed on the light transmitting layer and the first wavelength conversion layer;
a low refractive layer disposed on the capping layer; and
a second substrate disposed on the low refractive layer, wherein
the capping layer comprises a first surface facing the low refractive layer and a second surface opposite to the first surface,
in the first emission area, the second surface of the capping layer comprises a capping concave-convex pattern, and
in the second emission area, the second surface of the capping layer is substantially flat.

2. The display device of claim 1, wherein
the first wavelength conversion layer includes a light scatterer, and
the light transmitting layer does not include a light scatterer.

3. The display device of claim 1, wherein
the capping concave-convex pattern includes a plurality of depressed portions, and
each of the plurality of depressed portions of the capping concave-convex pattern is recessed in a thickness direction.

4. The display device of claim 1, wherein the capping concave-convex pattern includes a plurality of island-like patterns separated from each other.

5. The display device of claim 1, wherein the capping concave-convex pattern include a linear pattern extending in a direction.

6. The display device of claim 3, wherein a cross section of each of the plurality of depressed portions of the capping concave-convex pattern has a half-round, half-ellipse, or segment of a circle shape.

7. The display device of claim 3, wherein
a depth of each of the plurality of depressed portions of the capping concave-convex pattern is equal to or greater than about 0.1 m, and
a width of each of the plurality of depressed portions of the capping concave-convex pattern is equal to or greater than about 3 m.

8. The display device of claim 3, wherein a distance between the adjacent depressed portions is equal to or greater than about 1.5 m.

9. The display device of claim 1, wherein a refractive index of the light transmitting layer is in a range of about 1.40 to about 1.70.

10. The display device of claim 1, wherein
a refractive index of the capping layer is greater than a refractive index of the low refractive layer, and
a difference between the refractive index of the capping layer and the refractive index of the low refractive layer is in a range of about 0.30 to about 0.60.

11. The display device of claim 9, wherein
a refractive index of the capping layer is in a range of about 1.40 to about 1.70, and
a refractive index of the low refractive layer is in a range of about 1.10 to about 1.30.

12. The display device of claim 1, wherein an upper surface of the light transmitting layer is in contact with the second surface of the capping layer, and comprises a concave-convex pattern engaged with the capping concave-convex pattern.

13. The display device of claim 1, wherein
the second surface of the capping layer is in contact with an upper surface of the first wavelength conversion layer in the second emission area, and
the upper surface of the first wavelength conversion layer is substantially flat.

14. The display device of claim 1, wherein the first wavelength conversion layer includes a base resin and a first wavelength conversion shifter.

15. A display device comprising:
a first substrate comprising a first emission area and a second emission area;
a first light emitting element overlapping the first emission area and a second light emitting element overlapping the second emission area, the first and second light emitting elements disposed on the first substrate;
a light transmitting layer disposed on the first light emitting element;
a first wavelength conversion layer disposed on the second light emitting element;
a capping layer disposed on the light transmitting layer and the first wavelength conversion layer;
a low refractive layer disposed on the capping layer;
a first color filter disposed on the low refractive layer, overlapping the first emission area, and including a light scatterer;
a second color filter disposed on the low refractive layer and overlapping the second emission area; and
a second substrate disposed on the first color filter and the second color filter.

16. The display device of claim 15, wherein
the first wavelength conversion layer includes a light scatterer, and
the light transmitting layer and the second color filter do not include a light scatterer.

17. The display device of claim 16, wherein
the capping layer comprises a first surface facing the low refractive layer and a second surface opposite to the first surface,
in the first emission area, the second surface of the capping layer comprises a capping concave-convex pattern, and
in the second emission area, the second surface of the capping layer is substantially flat.

18. A method for fabrication of a display device, the method comprising:
preparing a substrate comprising a first transmission area, a second transmission area, and a light blocking area surrounding the first transmission area and the second transmission area;
forming a color filter layer on the substrate, forming a low refractive layer on the color filter layer, and forming a capping layer on the low refractive layer;
forming a capping concave-convex pattern on an upper surface of the capping layer in the first transmission area;
forming a bank pattern layer on the upper surface of the capping layer in the light blocking area; and
forming a light transmitting layer on the upper surface of the capping layer in the first transmission area.

19. The method of claim 18, further comprising, between the forming of the bank pattern layer and the forming of the light transmitting layer, or after the forming of the light transmitting layer,
forming a first wavelength conversion pattern layer on the upper surface of the capping layer in the second transmission area.

20. The method of claim 18, wherein the forming of the color filter layer on the substrate comprises:
forming a first color filter on the substrate to overlap the first transmission area and not to overlap the second transmission area; and
forming a second color filter on the substrate and the first color filter to overlap the second transmission area and not to overlap the first transmission area, wherein
the first color filter includes a light scatterer, and
the second color filter does not include a light scatterer.
